(19) United States
(12) Patent Application Publication
(10) Pub. No.: US 2019/0189673 A1
(43) Pub. Date: Jun. 20, 2019

(54) ACTIVE MATRIX SUBSTRATE, AND X-RAY IMAGING PANEL INCLUDING SAME

(71) Applicant: SHARP KABUSHIKI KAISHA, Sakai City (JP)

(72) Inventor: KATSUNORI MISAKI, Yonago-shi (JP)

(21) Appl. No.: 16/221,226

(22) Filed: Dec. 14, 2018

(30) Foreign Application Priority Data
Dec. 15, 2017 (JP) 2017-240800

(51) Int. Cl. H01L 27/146; G01T 1/20; H01L 27/12

(52) U.S. Cl. CPC H01L 27/14663; G01T 1/2018; H01L 27/1218; H01L 31/115; H01L 27/1288; H01L 27/14605; H01L 27/14612; H01L 27/1248

(57) ABSTRACT

An active matrix substrate 1 has a plurality of pixels, which each of pixels has a switching element. Each of the pixels includes a pair of electrodes 14a, 14b connected with the switching element; a photoelectric conversion element including a semiconductor layer 15 provided between the pair of electrodes; an inorganic film covering a surface of the photoelectric conversion element; and an organic resin film 106b covering the inorganic film. The inorganic film includes a first inorganic film 105a, and a second inorganic film 105b provided in a layer different from that of the first inorganic film 105a. The first inorganic film 105a is provided in contact with at least a side surface of the photoelectric conversion element, and the second inorganic film 105b is in contact with at least a part of the first inorganic film 105a and covers the side surface of the photoelectric conversion element.

### TECHNICAL FIELD

The present invention relates to an active matrix substrate, and an X-ray imaging panel including the same.

### BACKGROUND ART

Conventionally, a photoelectric conversion device has been known that includes an active matrix substrate provided with photoelectric conversion elements each of which is connected with a switching element in each pixel. Patent Document 1 discloses such a photoelectric conversion device. This photoelectric conversion device includes thin film transistors as switching elements, and includes photodiodes as photoelectric conversion elements. In the photodiode, a p-type semiconductor layer, an i-type semiconductor layer, and an n-type semiconductor layer are used as semiconductor layers, and electrodes are connected to the p-type semiconductor layer and the n-type semiconductor layer, respectively. The photodiode is covered with a resin film made of an epoxy resin.

### PRIOR ART DOCUMENT

### Patent Document

### Patent Document 1: JP-A-2007-165865

### SUMMARY OF THE INVENTION

### Problem to be Solved by the Invention

Incidentally, after an imaging panel is produced, a surface of the imaging panel is scarred in some cases. If moisture in the atmosphere gets in the inside through scars of the imaging panel surface, leakage current in semiconductor layers of photodiodes tends to flow in between electrodes. More specifically, for example, in the imaging panel illustrated in FIG. 27A, moisture gets in the inside through a scar J of the imaging panel surface, moisture permeates the resin film 22 on the photodiode 12. FIG. 27B is an enlarged view illustrating a part of a broken line frame 210 illustrated in FIG. 27A. As illustrated in FIG. 27B, the photodiode 12 is covered with an inorganic film 21, but in step-like parts of end portions of a semiconductor layer 122 and an electrode 121a in the photodiode 12, the inorganic film 21 tends to be discontinuous. If moisture permeates the resin film 22, and moisture gets in the inside through a part 2101 where the inorganic film 21 is discontinuous, the inorganic film 21 becomes a leakage path through which leakage current of the semiconductor layer 122 flows, and leakage current flows between the electrodes 121a and 121b (see FIG. 27A). When leakage current flows between the electrodes 121a and 121b, X-ray detection accuracy decreases.

The present invention provides a technique that enables to prevent decreases in the detection accuracy caused by leakage current of photoelectric conversion elements.

### Means to Solve the Problem

An active matrix substrate of the present invention that solves the above-described problem is an active matrix substrate having a plurality of pixels, wherein each of the pixels includes: a switching element; a photoelectric conversion element including a pair of electrodes connected with the switching element, and a semiconductor layer provided between the pair of electrodes; an inorganic film covering a surface of the photoelectric conversion element; and an organic resin film covering the inorganic film, wherein the inorganic film includes a first inorganic film, and a second inorganic film provided in a layer different from that of the first inorganic film, the first inorganic film is provided in contact with at least a side surface of the photoelectric conversion element, and the second inorganic film is provided so as to be in contact with at least a part of the first inorganic film and cover the side surface of the photoelectric conversion element.

### Effect of the Invention

The present invention makes it possible to prevent decreases in the detection accuracy caused by leakage current of photoelectric conversion elements.

### BRIEF DESCRIPTION OF DRAWINGS

FIG. 1 schematically illustrates an X-ray imaging device in Embodiment 1.

FIG. 2 schematically illustrates a schematic configuration of an active matrix substrate in FIG. 1.

FIG. 3 is an enlarged plan view illustrating a part of a pixel part of the active matrix substrate illustrated in FIG. 2 in which pixels are provided.

FIG. 4 is a cross-sectional view of the pixel part illustrated in FIG. 3 taken along line A-A.

FIG. 5A is a view for explaining a step for producing the pixel part illustrated in FIG. 4, which is a cross-sectional view illustrating a state in which a TFT is formed in the pixel part.

FIG. 5B is a cross-sectional view illustrating a step of forming a first insulating film.

FIG. 5C is a cross-sectional view illustrating a step of forming an opening in the first insulating film.

FIG. 5D is a cross-sectional view illustrating a step of forming a second insulating film.

FIG. 5E is a cross-sectional view illustrating a step of forming a contact hole CH1.

FIG. 5F is a cross-sectional view illustrating a step of forming a lower electrode.

FIG. 5G is a cross-sectional view illustrating a step of forming an upper electrode.

FIG. 5H is a cross-sectional view illustrating a step of forming a photoelectric conversion layer.

FIG. 5I is a cross-sectional view illustrating a step of forming a 3a-th insulating film.

FIG. 5J is a cross-sectional view illustrating a step of forming an opening in the 3a-th insulating film.

FIG. 5K is a cross-sectional view illustrating a step of forming a 4a-th insulating film.

FIG. 5L is a cross-sectional view illustrating a step of forming an opening in the 4a-th insulating film.

FIG. 5M is a cross-sectional view illustrating a step of forming a 3b-th insulating film.

FIG. 5N is a cross-sectional view illustrating a step of forming an opening in the 3b-th insulating film.

FIG. 5O is a cross-sectional view illustrating a step of forming a 4b-th insulating film.

FIG. 5P is a cross-sectional view illustrating a step of forming an opening in the 4b-th insulating film.

FIG. 5Q is a cross-sectional view illustrating a step of forming a metal film that becomes a bias line.

FIG. 5R is a cross-sectional view illustrating a step of forming the bias line.

FIG. 5S is a cross-sectional view illustrating a step of forming a transparent conductive film connecting the bias line and the photoelectric conversion layer illustrated in FIG. 5R.

FIG. 5T is a cross-sectional view illustrating a step of forming a fifth insulating film.

FIG. 5U is a cross-sectional view illustrating a step of forming a sixth insulating film.

FIG. 6 is an enlarged cross-sectional view illustrating a part of a pixel part in Embodiment 2.

FIG. 7A is a view for explaining a step for producing the pixel part illustrated in FIG. 6, which is a cross-sectional view illustrating a step for patterning a 3a-th insulating film.

FIG. 7B is a cross-sectional view illustrating a step of forming a 4a-th insulating film illustrated in FIG. 6.

FIG. 7C is a cross-sectional view illustrating a step of forming an opening in the 4a-th insulating film illustrated in FIG. 7B.

FIG. 7D is a cross-sectional view illustrating a step of forming a 3b-th insulating film.

FIG. 7E is a cross-sectional view illustrating a step for patterning the 3b-th insulating film illustrated in FIG. 7D.

FIG. 8 is an enlarged cross-sectional view illustrating a part of a pixel part in Embodiment 3.

FIG. 9A is a cross-sectional view illustrating a step for patterning a 3a-th insulating film illustrated in FIG. 8.

FIG. 9B is a cross-sectional view illustrating a step of forming a 4a-th insulating film.

FIG. 9C is a cross-sectional view illustrating a step for patterning the 4a-th insulating film illustrated in FIG. 9B.

FIG. 9D is a cross-sectional view illustrating a step of forming a 3b-th insulating film.

FIG. 9E is a cross-sectional view illustrating a step for patterning the 3b-th insulating film illustrated in FIG. 9D.

FIG. 10 is an enlarged cross-sectional view illustrating a part of a pixel part in Embodiment 4.

FIG. 11 is a cross-sectional view illustrating a step for patterning a 4a-th insulating film illustrated in FIG. 10.

FIG. 12 is an enlarged cross-sectional view illustrating a part of a pixel part in Embodiment 5.

FIG. 13A is a cross-sectional view illustrating a step of forming a 4a-th insulating film illustrated in FIG. 12.

FIG. 13B is a cross-sectional view illustrating a step for patterning the 4a-th insulating film illustrated in FIG. 13A.

FIG. 13C is a cross-sectional view illustrating a step of forming a 3b-th insulating film illustrated in FIG. 12.

FIG. 13D is a cross-sectional view illustrating a step for patterning the 3a-th insulating film and the 3b-th insulating film illustrated in FIG. 13C.

FIG. 13E is a cross-sectional view illustrating a step of forming a 4b-th insulating film.

FIG. 13F is a cross-sectional view illustrating a step of forming an opening in the 4b-th insulating film.

FIG. 14 is an enlarged cross-sectional view illustrating a part of a pixel part in Embodiment 6.

FIG. 15 is a cross-sectional view illustrating a step for patterning the 4a-th insulating film illustrated in FIG. 14.

FIG. 16 is an enlarged cross-sectional view illustrating a part of a pixel part according to Embodiment 7 (7-1).

FIG. 17A is a cross-sectional view illustrating a step of forming a 3b-th insulating film illustrated in FIG. 16.

FIG. 17B is a cross-sectional view illustrating a step of forming an opening in the 3b-th insulating film illustrated in FIG. 17A.

FIG. 18 is an enlarged cross-sectional view illustrating a part of a pixel part according to Embodiment 7 (7-2).

FIG. 19A is a cross-sectional view illustrating a step of forming a 3b-th insulating film illustrated in FIG. 18.

FIG. 19B is a cross-sectional view illustrating a step of forming an opening in the 3b-th insulating film illustrated in FIG. 19A.

FIG. 20 is an enlarged cross-sectional view illustrating a part of a pixel part according to Embodiment 7 (7-3).

FIG. 21 is a cross-sectional view illustrating a structure of the pixel part that is different from that illustrated in FIG. 20.

FIG. 22 illustrates the relationship between the thickness and the transmittance of an inorganic insulating film.

FIG. 23 is an enlarged cross-sectional view illustrating a part of a pixel part in (1) according to Modification Example 1.

FIG. 24A is a view for explaining a step of forming the pixel part illustrated in FIG. 23, which is a cross-sectional view illustrating a step of forming an opening in the 4a-th insulating film illustrated in FIG. 23.

FIG. 24B is a cross-sectional view illustrating a step of forming a 3b-th insulating film illustrated in FIG. 23.

FIG. 24C is a cross-sectional view illustrating a step of forming an opening in the 3b-th insulating film and the 3a-th insulating film illustrated in FIG. 24B.

FIG. 24D is a cross-sectional view illustrating a step of forming a 4b-th insulating film illustrated in FIG. 23.

FIG. 24E is a cross-sectional view illustrating a step of forming an opening in the 4b-th insulating film illustrated in FIG. 24D.

FIG. 25 is an enlarged cross-sectional view illustrating a part of a pixel part in (2) according to Modification Example 1.

FIG. 26A is a view for explaining a step of forming the pixel part illustrated in FIG. 25, which is a cross-sectional view illustrating a step of forming a metal film as a lower electrode, and a resist used for forming the lower electrode.

FIG. 26B is a cross-sectional view illustrating a state in which a metal film illustrated in FIG. 26A is etched.

FIG. 26C is a cross-sectional view illustrating a state in which the resist illustrated in FIG. 26B is removed and a lower electrode is formed.

FIG. 26D is a cross-sectional view illustrating a step of forming the 4a-th insulating film illustrated in FIG. 25, and forming an opening in the 4a-th insulating film.

FIG. 26E is a cross-sectional view illustrating a step of forming the 3b-th insulating film illustrated in FIG. 25, and forming an opening in the 3a-th insulating film and the 3b-th insulating film.

FIG. 26F is a cross-sectional view illustrating a 4b-th insulating film illustrated in FIG. 25 on the 3b-th insulating film illustrated in FIG. 26E, and forming an opening in the 4b-th insulating film.

FIG. 27A is a cross-sectional view illustrating an exemplary structure of a conventional active matrix substrate used in an X-ray imaging device.

FIG. 278B is an enlarged cross-sectional view illustrating a part in a broken line frame 210 illustrated in FIG. 27A.

### MODE FOR CARRYING OUT THE INVENTION

An active matrix substrate according to one embodiment of the present invention is an active matrix substrate having a plurality of pixels, wherein each of the pixels includes: a switching element; a photoelectric conversion element including a pair of electrodes connected with the switching element, and a semiconductor layer provided between the pair of electrodes; an inorganic film covering a surface of the photoelectric conversion element; and an organic resin film covering the inorganic film, wherein the inorganic film includes a first inorganic film, and a second inorganic film provided in a layer different from that of the first inorganic film, the first inorganic film is provided in contact with at least a side surface of the photoelectric conversion element, and the second inorganic film is provided so as to be in contact with at least a part of the first inorganic film and cover the side surface of the photoelectric conversion element (the first configuration).

According to the first configuration, the first inorganic film is provided in contact with the side surface of the photoelectric conversion element, and further, the side surface of the photoelectric conversion element is covered with the second inorganic film provided in contact with the first inorganic film. Therefore, in a case where the first inorganic film covering the side surface of the photoelectric conversion element has a discontinuous part, even if moisture permeates the organic resin film, the second inorganic film makes it unlikely that moisture would get in the inside the first inorganic film. As a result, it is unlikely that the first inorganic film would serves as a leakage path for leakage current of the photoelectric conversion element, whereby light detection accuracy hardly decreases.

The first configuration may be further characterized in that either the first inorganic film or the second inorganic film is arranged so as to be in contact with one of the pair of electrodes (the second configuration).

With the second configuration, one of the electrodes of the photoelectric conversion element can be protected by either the first inorganic film or the second inorganic film.

The first configuration may be further characterized in that the first inorganic film is arranged so as to be in contact with one of the pair of electrodes, and the second inorganic film is arranged so as to overlap with the one of the electrodes with the first inorganic film being interposed therebetween (the third configuration).

According to the third configuration, one of the electrodes of the photoelectric conversion element is covered with the first inorganic film and the second inorganic film. Accordingly, as compared with a case of being covered with either one of the inorganic films, the electrode can be protected more surely.

Any one of the first to third configurations may be further characterized in that the organic resin film includes a first organic resin film, and a second organic resin film provided in a layer different from that of the first organic resin film; the first organic resin film is provided between the first inorganic film and the second inorganic film, so as to overlap with the side surface of the photoelectric conversion element when viewed in a plan view; and the second organic resin film is provided so as to cover the second inorganic film (the fourth configuration).

According to the fourth configuration, the side surface of the photoelectric conversion element is covered with the first inorganic film, the second organic resin film, and the second inorganic film. Therefore, as compared with a case where the second organic resin film is not provided, the permeation of moisture into the second inorganic film can be prevented further.

The fourth configuration may be further characterized in that the first inorganic film and the first organic resin film of each pixel is positioned apart from the first inorganic film and the first organic resin film of another adjacent pixel, respectively (the fifth configuration).

According to the fifth configuration, the first inorganic film and the first organic resin film are arranged so as to be divided and separated between adjacent pixels. In a case where moisture gets in the inside of the first inorganic film and the second organic resin film at a certain pixel, if there is a discontinuous part in the first inorganic film covering the side surface of the photoelectric conversion element of the pixel, moisture gets into the discontinuous part, thereby causing the first inorganic film to become a leakage path. The first inorganic film and the first organic resin film, however, are divided and separated between the pixels, whereby the leakage path does not extend to another adjacent pixel.

The first or second configuration may be further characterized in that the first inorganic film and the second inorganic film overlap with each other at the side surface of the photoelectric conversion element, and the organic resin film is arranged so as to cover the first inorganic film and the second inorganic film (the sixth configuration).

According to the sixth configuration, the side surface of the photoelectric conversion element is covered with the first inorganic film and the second inorganic film. Even though the first inorganic film covering the side surface of the photoelectric conversion element has a discontinuous part, when moisture permeates the organic resin film, it is therefore unlikely that moisture would get in the discontinuous part and a leakage path would be formed in the first inorganic film.

Any one of the first to sixth configurations may be further characterized in that each of the first inorganic film and the second inorganic film has a thickness of an integer multiple of 150 nm (the seventh configuration).

With the seventh configuration, the photoelectric conversion efficiency in the photoelectric conversion element can be improved.

An X-ray imaging panel according to one embodiment of the present invention includes: the active matrix substrate according to any one of the first to seventh configurations; and a scintillator that converts irradiated X-rays into scintillation light (the eighth configuration).

According to the eighth configuration, the first inorganic film is provided in contact with the side surface of the photoelectric conversion element, and further, the side surface of the photoelectric conversion element is covered with the second inorganic film provided in contact with the first inorganic film. Therefore, in a case where the first inorganic film covering the side surface of the photoelectric conversion element has a discontinuous part, even if moisture penetrates through the organic resin film covering the first inorganic film and the second inorganic film, the second inorganic film makes it unlikely that moisture would get in the inside the first inorganic film. As a result, it is unlikely that the first inorganic film would serves as a leakage path for leakage current of the photoelectric conversion element, whereby X-ray detection accuracy hardly decreases.

The following description describes embodiments of the present invention in detail, while referring to the drawings. Identical or equivalent parts in the drawings are denoted by the same reference numerals, and the descriptions of the same are not repeated.

### Embodiment 1

### (Configuration)

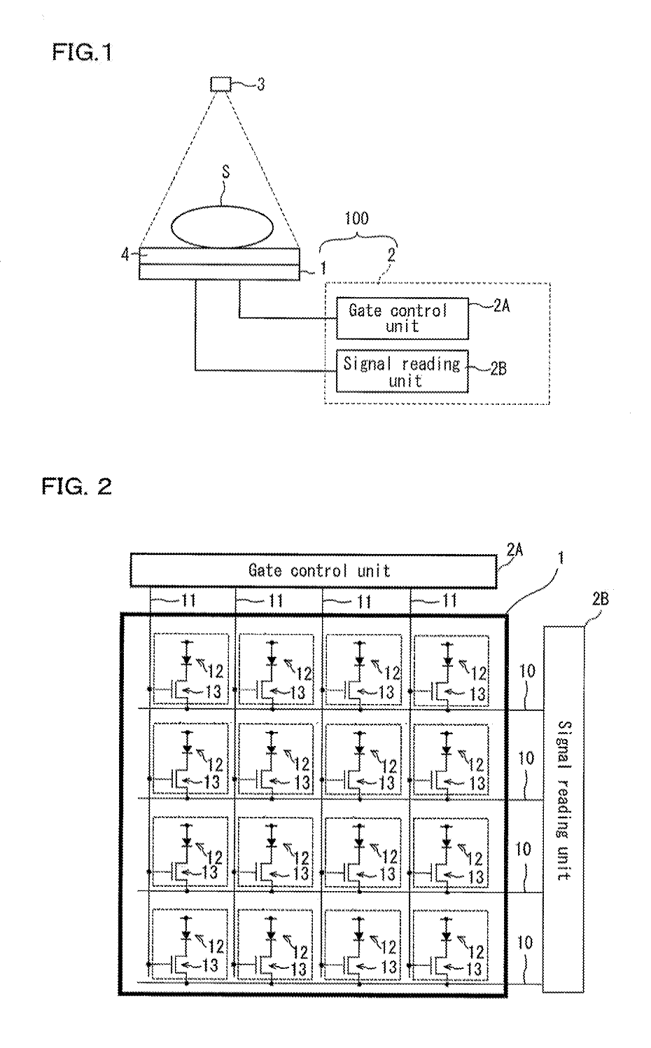

FIG. 1 schematically illustrates an X-ray imaging device to which an active matrix substrate of the present embodiment is applied. The X-ray imaging device 100 includes an active matrix substrate 1 and a control unit 2. The control unit 2 includes a gate control unit 2A and a signal reading unit 2B. X-rays are emitted from an X-ray source 3 to an object S. X-rays transmitted through the object S are converted into fluorescence (hereinafter referred to as scintillation light) by a scintillator 4 provided on the active matrix substrate 1. The X-ray imaging device 100 obtains an X-ray image by picking up scintillation light with use of the active matrix substrate 1 and the control unit 2.

FIG. 2 schematically illustrates a schematic configuration of the active matrix substrate 1. As illustrated in FIG. 2, a plurality of source lines 10, and a plurality of gate lines 11 that intersect with the source lines 10, are formed on the active matrix substrate 1. The gate lines 11 are connected with the gate control unit 2A, and the source lines 10 are connected with the signal reading unit 2B.

The active matrix substrate 1 includes TFTs 13 connected to the source lines 10 and the gate lines 11, at positions where the source lines 10 and the gate lines 11 intersect. Further, in areas surrounded by the source lines 10 and the gate lines 11 (hereinafter referred to as pixels), photodiodes 12 are provided, respectively. In each pixel, the photodiode 12 converts scintillation light obtained by converting X-rays transmitted through the object S, into charges in accordance with the amount of the light.

The gate lines 11 on the active matrix substrate 1 are sequentially switched by the gate control unit 2A into a selected state, and the TFT 13 connected to the gate line 11 in the selected state is turned ON. When the TFT 13 is turned ON, a signal according to the charges obtained by conversion in the photodiode 12 is output to the signal reading unit 2B through the source line 10.

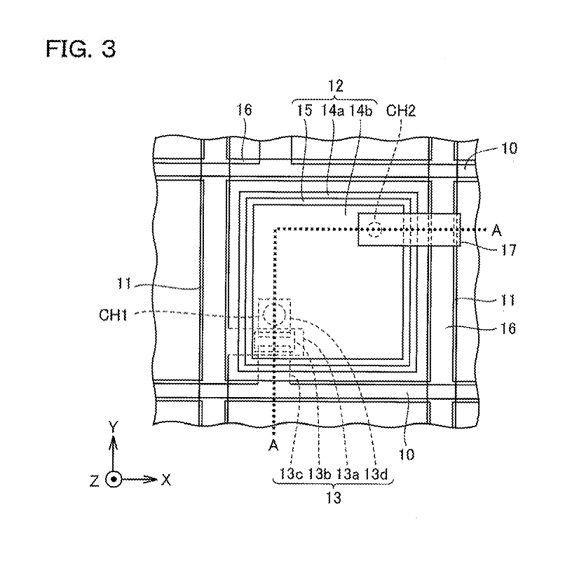

FIG. 3 is an enlarged plan view illustrating a part of a pixel part of the active matrix substrate 1 illustrated in FIG. 2 in which pixels are provided.

As illustrated in FIG. 3, the pixel surrounded by the gate lines 11 and the source lines 10 has the photodiode 12 and the TFT 13.

The photodiode 12 includes a lower electrode 14a, a photoelectric conversion layer 15, and an upper electrode 14b. The TFT 13 includes a gate electrode 13a integrated with the gate line 11, a semiconductor activity layer 13b, a source electrode 13c integrated with the source line 10, and a drain electrode 13d. The drain electrode 13d and the lower electrode 14a are connected with each other via a contact hole CH1.

Further, a bias line 16 is arranged so as to overlap with the gate line 11 and the source line 10 when viewed in a plan view. The bias line 16 is connected with a transparent conductive film 17. The transparent conductive film 17 supplies a bias voltage to the photodiode 12 via a contact holes CH2.

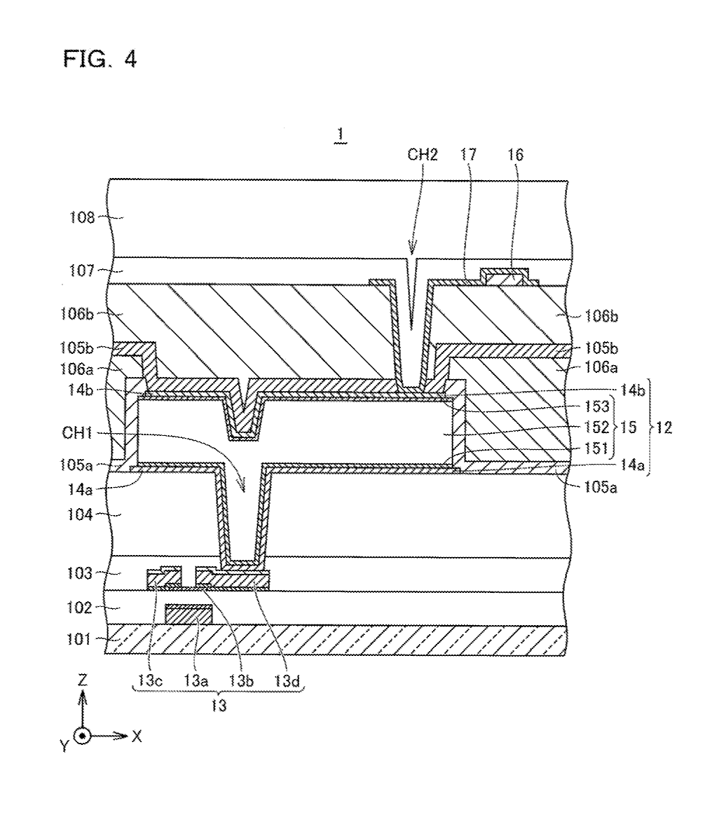

Here, FIG. 4 illustrates a cross-sectional view taken along line A-A in the pixel part P1 of FIG. 3. As illustrated in FIG. 4, the gate electrode 13a integrated with the gate line 11 (see FIG. 3), and the gate insulating film 102, are formed on the substrate 101. The substrate 101 is has insulating property, and is formed with, for example, a glass substrate or the like.

The gate electrode 13a and the gate line 11 are formed by laminating, for example, a metal film made of titanium (Ti) in the lower layer, and a metal film made of copper (Cu) in the upper layer. The gate electrode 13a and the gate line 11 may have a structure obtained by laminating a metal film made of aluminum (Al) in the lower layer, and a metal film made of molybdenum nitride (MoN) in the upper layer. In this example, the metal films in the lower layer and the upper layer have thicknesses of about 300 nm and 100 nm, respectively. The material and thickness of the gate electrode 13a and the gate line 11, however, are not limited to these.

The gate insulating film 102 covers the gate electrode 13a. To form the gate insulating film 102, the following may be used, for example: silicon oxide (SiOₓ); silicon nitride (SiNₓ); silicon oxide nitride (SiOₓN_{y})(x>y); silicon nitride oxide (SiNₓO_{y})(x>y); or the like. In the present embodiment, the gate insulating film 102 is formed by laminating an insulating film made of silicon oxide (SiOₓ) in the upper layer, and an insulating film made of silicon nitride (SiNₓ) in the lower layer. In this example, the insulating film made of silicon oxide (SiOₓ) has a thickness of about 50 nm, and the insulating film made of silicon nitride (SiNₓ) has a thickness of about 400 nm. The material and the thickness of the gate insulating film 102, however, are not limited to these.

A semiconductor activity layer 13b, and a source electrode 13c and a drain electrode 13d connected with the semiconductor activity layer 13b, are provided on the gate electrode 13a with the gate insulating film 102 being interposed therebetween.

The semiconductor activity layer 13b is in contact with the gate insulating film 102. The semiconductor activity layer 13b is made of an oxide semiconductor. As the oxide semiconductor, for example, the following may be used: InGaO₃(ZnO)₅; magnesium zinc oxide (MgₓZn₁₋ₓO); cadmium zinc oxide (CdₓZn₁₋ₓO); cadmium oxide (CdO); or an amorphous oxide semiconductor containing indium (In), gallium (Ga), and zinc (Zn) at a predetermined ratio. In this example, the semiconductor activity layer 13b is made of an amorphous oxide semiconductor containing indium (In), gallium (Ga), and zinc (Zn) at a predetermined ratio. In this example, the semiconductor activity layer 13b has a thickness of about 70 nm. The material and the thickness of the semiconductor activity layer 13b, however, are not limited to these.

The source electrode 13c and the drain electrode 13d are arranged so as to be in contact with a part of the semiconductor activity layer 13b on the gate insulating film 102. In this example, the source electrode 13c is integrally formed with the source line 10 (see FIG. 3). The drain electrode 13d is connected with the lower electrode 14a via the contact hole CH1.

The source electrode 13c and the drain electrode 13d are provided on the same layer. The source electrode 13c and drain electrode 13d have a three-layer structure obtained by laminating, for example, a metal film made of molybdenum nitride (MoN), a metal film made of aluminum (Al), and a metal film made of titanium (Ti). In this example, these three layers have thicknesses of about 100 nm, 500 nm, and 50 nm, respectively, in the order from the upper layer. The material and the thickness of the source electrode 13c and drain electrode 13d, however, are not limited to these.

On the gate insulating film 102, a first insulating film 103 is provided so as to overlap with the source electrode 13c and drain electrode 13d. The first insulating film 103 has an opening on the drain electrode 13d. The first insulating film 103 has a structure laminated silicon nitride (SiN) and silicon oxide (SiO₂) in the stated order.

On the first insulating film 103, a second insulating film 104 is provided. The second insulating film 104 has an opening on the drain electrode 13d, and the contact hole CH1 is formed with the opening of the first insulating film 103 and the opening of the second insulating film 104 form.

The second insulating film 104 is made of, for example, an organic transparent resin such as an acrylic resin or a siloxane-based resin, and has a thickness of about 2.5 μm. The material and the thickness of the second insulating film 104, however, are not limited to these.

On the second insulating film 104, the lower electrode 14a is provided. The lower electrode 14a is connected with the drain electrode 13d via the contact hole CH1. The lower electrode 14a is formed with, for example, a metal film containing molybdenum nitride (MoN). In this example, the lower electrode 14b has a thickness of about 200 nm, but the thickness thereof is not limited to this.

On the lower electrode 14a, the photoelectric conversion layer 15 is provided. The photoelectric conversion layer 15 has such a configuration that an n-type amorphous semiconductor layer 151, an intrinsic amorphous semiconductor layer 152, and a p-type amorphous semiconductor layer 153 are laminated in the stated order. In this example, the photoelectric conversion layer 15 has a length in the X axis direction which is smaller than the length of the lower electrode 14a in the X axis direction.

The n-type amorphous semiconductor layer 151 is made of amorphous silicon doped with an n-type impurity (for example, phosphorus).

The intrinsic amorphous semiconductor layer 152 is made of intrinsic amorphous silicon. The intrinsic amorphous semiconductor layer 152 is in contact with the n-type amorphous semiconductor layer 151.

The p-type amorphous semiconductor layer 153 is made of amorphous silicon doped with a p-type impurity (for example, boron). The p-type amorphous semiconductor layer 153 is in contact with the intrinsic amorphous semiconductor layer 152.

In this example, the n-type amorphous semiconductor layer 151 has a thickness of about 30 nm, the intrinsic amorphous semiconductor layer has a thickness of about 1000 nm, and the p-type amorphous semiconductor layer 153 has a thickness of about 5 nm; the thicknesses thereof, however, are not limited to these.

On the photoelectric conversion layer 15, the upper electrode 14b is provided. The upper electrode 14b is made of, for example, indium tin oxide (ITO), and has a thickness of about 70 nm. The material and the thickness of the upper electrode 14b, however, are not limited to these.

A 3a-th insulating film 105a and a 3b-th insulating film 105b as inorganic films are provided so as to be in contact with the surface of the photodiode 12. The 3a-th insulating film 105a and the 3b-th insulating film 105b are provided so as to be positioned apart from each other in the direction vertical to the substrate 101 outside the photodiode 12. Between the 3a-th insulating film 105a and the 3b-th insulating film 105b, a 4a-th insulating film 106a as an organic resin film is provided. Further, on the 3b-th insulating film 105b, a 4b-th insulating film 106b as an organic resin film is provided.

More specifically, the 3a-th insulating film 105a is provided so as to extend from vicinities of ends on both sides of the upper electrode 14b, to be in contact with side surface portions of the photodiode 12, and to cover the second insulating film 104. In other words, the 3a-th insulating film 105a is arranged so as to be divided and separated above the upper electrode 14b, and so as to cover the side surfaces of the photodiode 12 and the second insulating film 104.

The 3b-th insulating film 105b is in contact with the 3a-th insulating film 105a on the upper electrode 14b, and has an opening in a part of the surface of the upper electrode 14b where the 3a-th insulating film 105a is not provided. The 3b-th insulating film 105b is formed extending to outside the photodiode 12, covering side surfaces of the photodiode 12 with the 4a-th insulating film 106a being interposed therebetween.

In other words, in the present embodiment, the 3a-th insulating film 105a, the 4a-th insulating film 106a, and the 3b-th insulating film 105b arranged outside the photodiode 12 are extended to the photodiode 12 of the adjacent pixel.

The 4b-th insulating film 106b is provided on the 3b-th insulating film 105b so that the 4b-th insulating film 106b has an opening above the opening of the 3b-th insulating film 105b. The contact hole CH2 is formed with the openings of the 3b-th insulating film 105b and the 4b-th insulating film 106b form.

In this example, the 3a-th insulating film 105a and the 3b-th insulating film 105b are made of, for example, silicon nitride (SiN), and each of the same has a thickness of about 300 nm; the materials and the thicknesses of these, however, are not limited to these.

The 4a-th insulating film 106a and the 4b-th insulating film 106b are made of an organic transparent resin composed of, for example, an acrylic resin or a siloxane-based resin, and these have thicknesses of, for example, about 1.5 μm and 1.0 μm, respectively; the materials and the thicknesses of the 4a-th insulating film 106a and the 4b-th insulating film 106b, however, are not limited to these.

On the 4b-th insulating film 106b, the bias line 16, as well as the transparent conductive film 17 connected with the bias line 16, are provided. The transparent conductive film 17 is in contact with the upper electrode 14b at the contact hole CH2.

The bias line 16 is connected to the control unit 2 (see FIG. 1). The bias line 16 applies a bias voltage input from the control unit 2, to the upper electrode 14b via the contact hole CH2.

The bias line 16 has a three-layer structure. More specifically, the bias line 16 has a structure obtained by laminating, in the order from the upper layer, a metal film made of molybdenum nitride (MoN), a metal film made of aluminum (Al), and a metal film made of titanium (Ti). In this example, the metal films of these three layers have thicknesses of, in the order from the upper layer, about 100 nm, 300 nm, and 50 nm, respectively. The materials and the thicknesses of the bias line 16, however, are not limited to these.

The transparent conductive film 17 is made of, for example, ITO, and has a thickness of about 70 nm: the material and the thickness of the transparent conductive film 17, however, are not limited to these.

Further, on the 4b-th insulating film 106b, a fifth insulating film 107 as an inorganic insulating film is provided so as to cover the transparent conductive film 17. The fifth insulating film 107 is made of, for example, silicon nitride (SiN), and has a thickness of, for example, about 200 nm; the material and the thickness of the fifth insulating film 107, however, are not limited to these.

A sixth insulating film 108 made of a resin film is provided so as to cover the fifth insulating film 107. The sixth insulating film 108 is formed with an organic transparent resin made of, for example, an acrylic resin or a siloxane-based resin, and has a thickness of, for example, about 2.0 μm; the material and the thickness of the sixth insulating film 108, however, are not limited to these.

### (Method for Producing the Active Matrix Substrate 1)

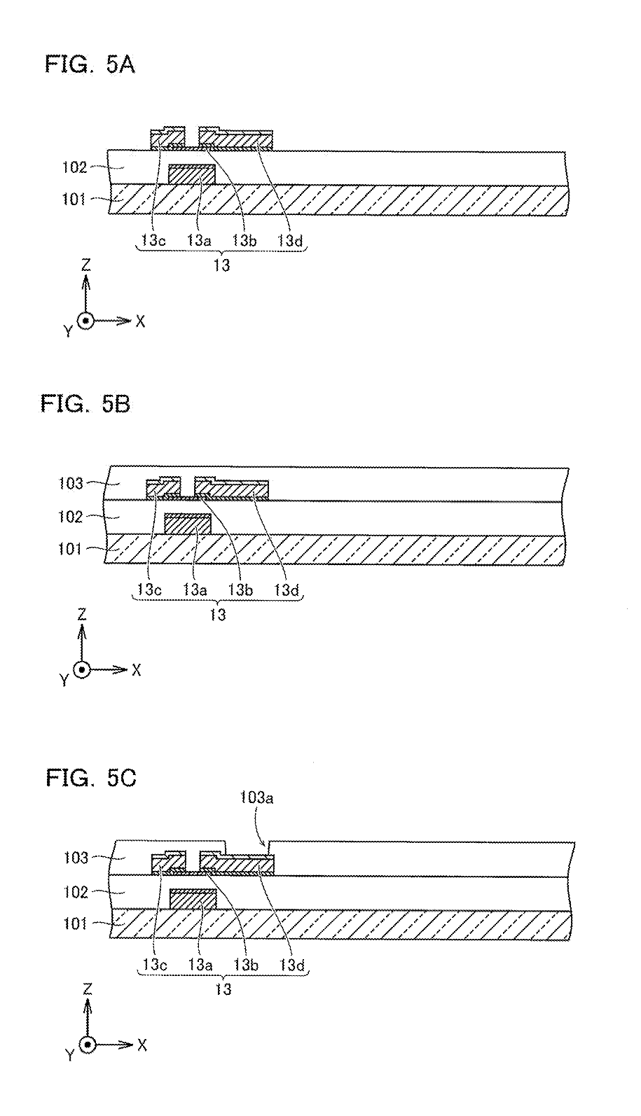

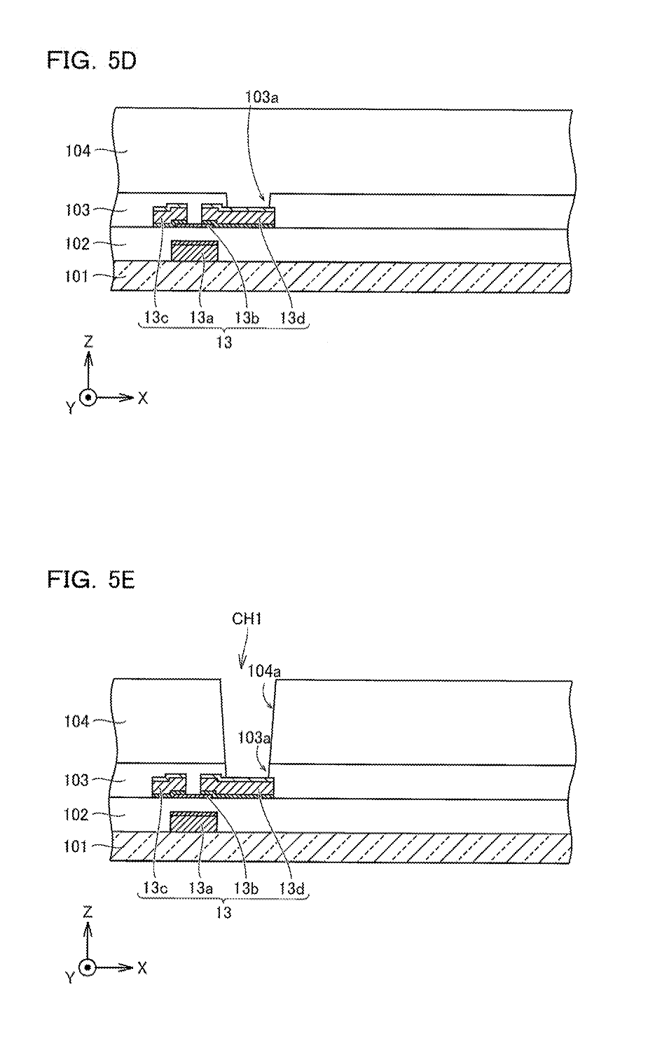

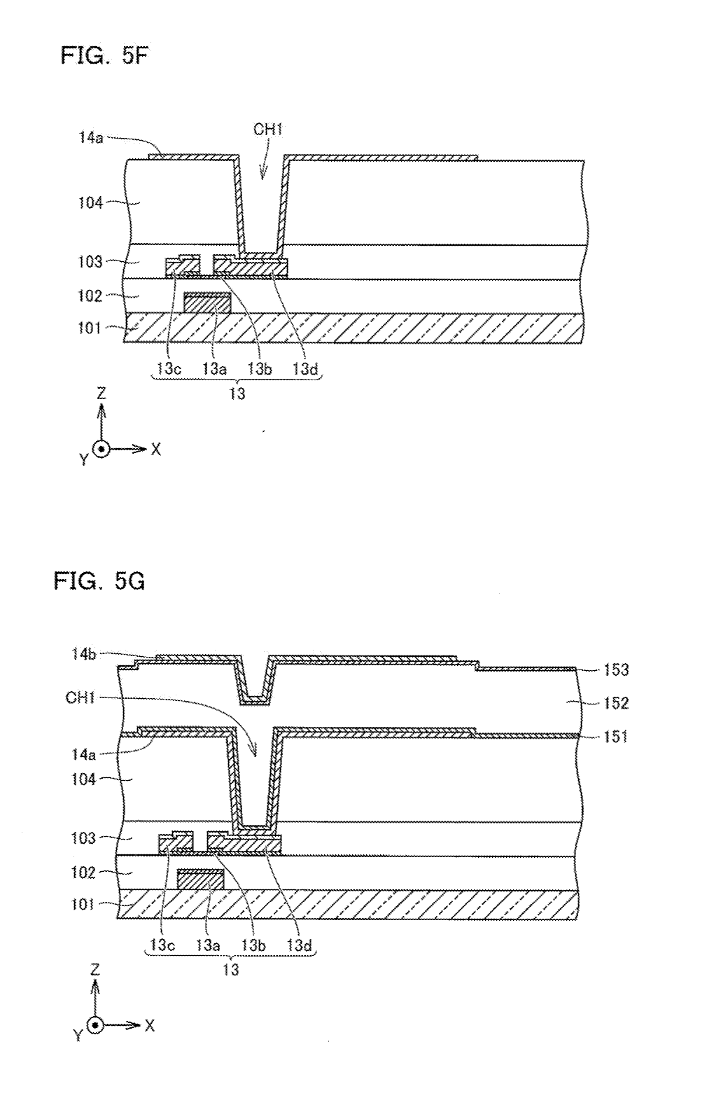

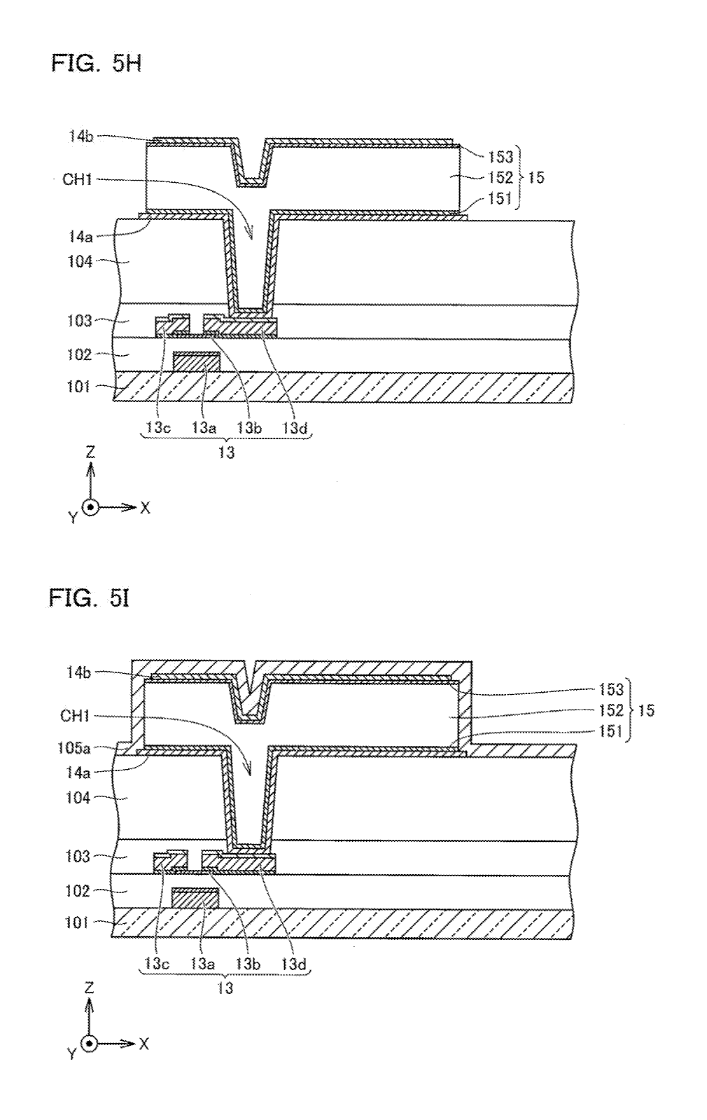

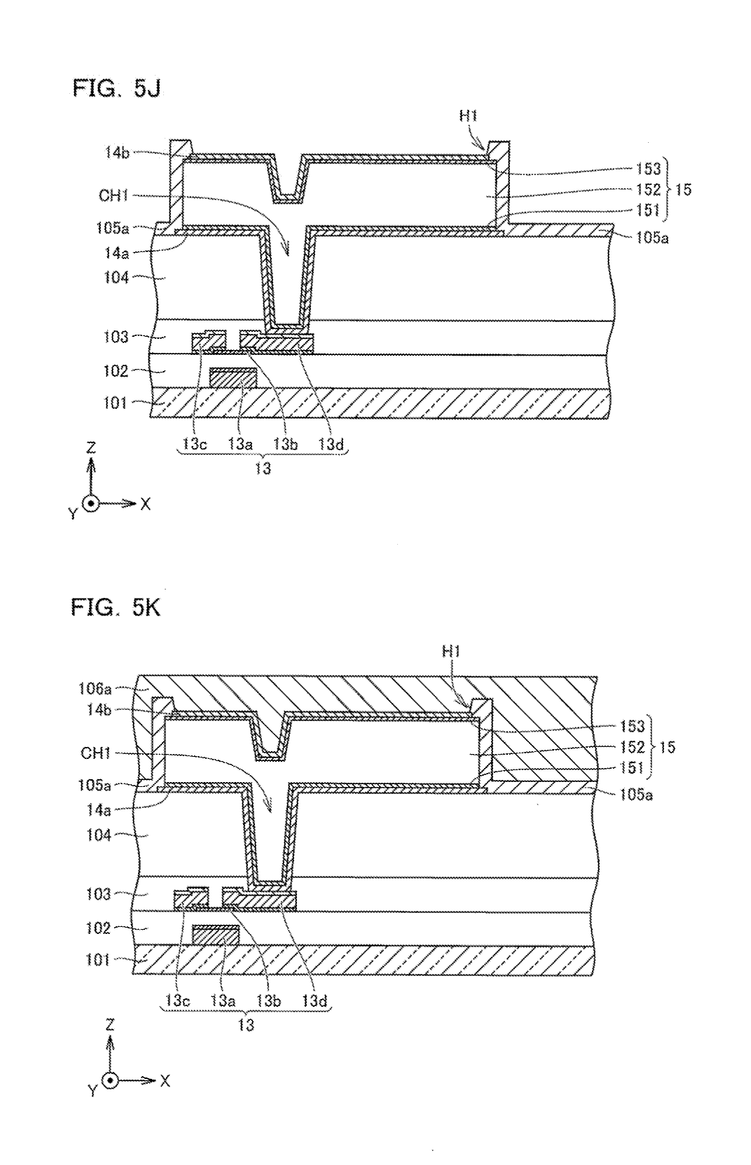

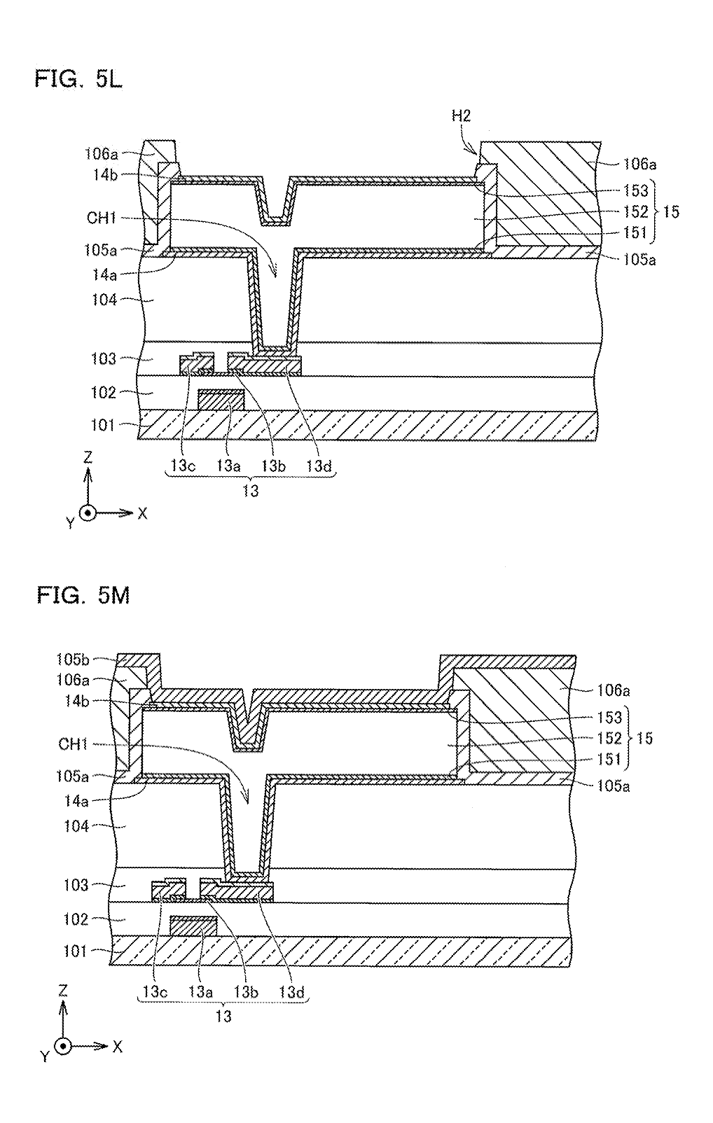

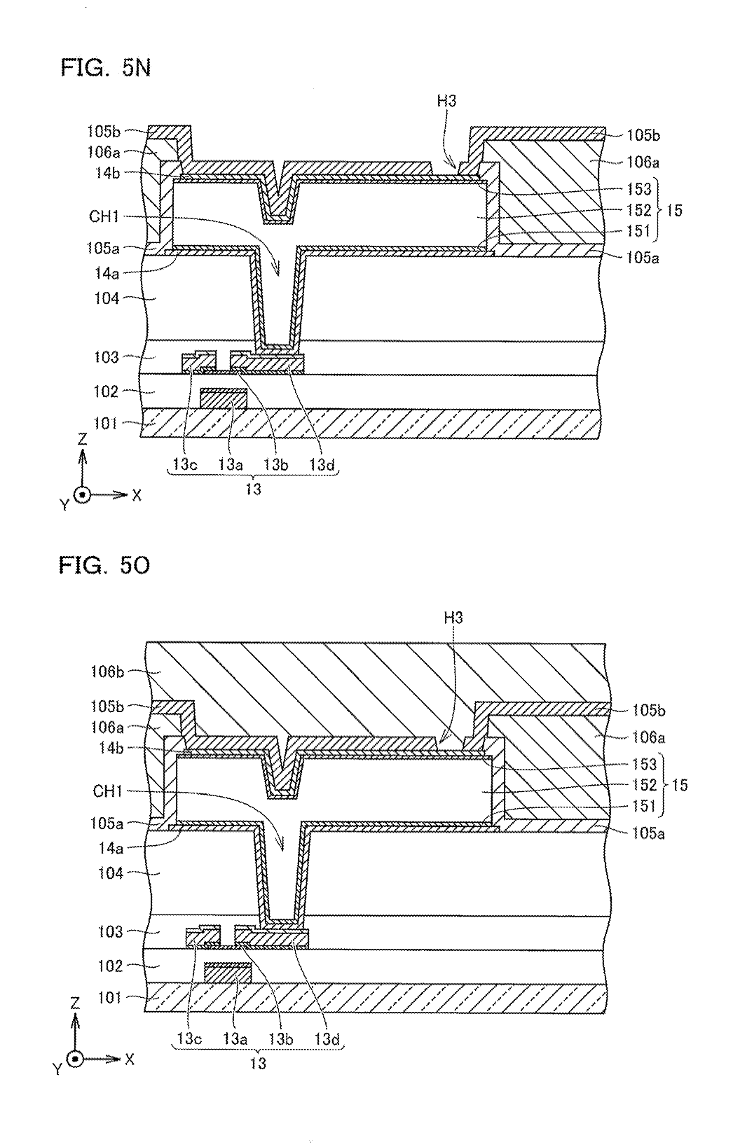

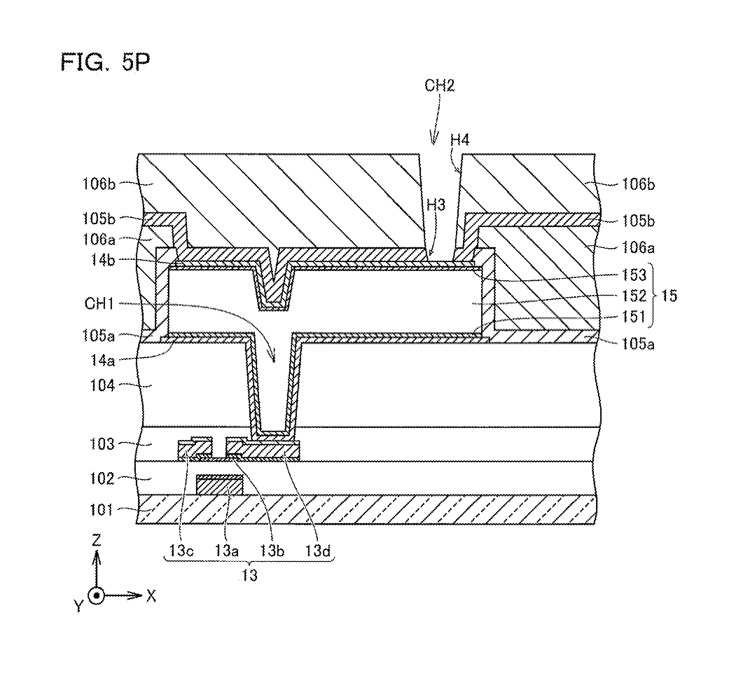

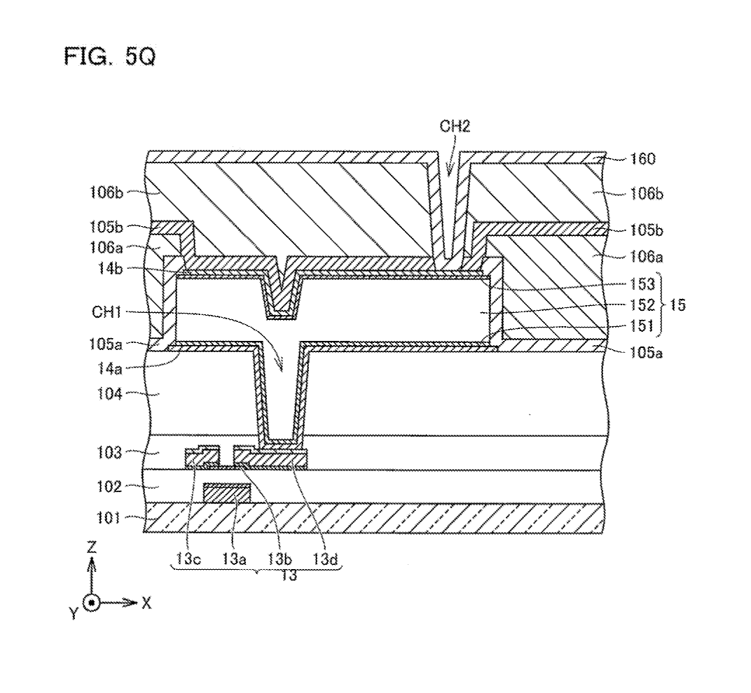

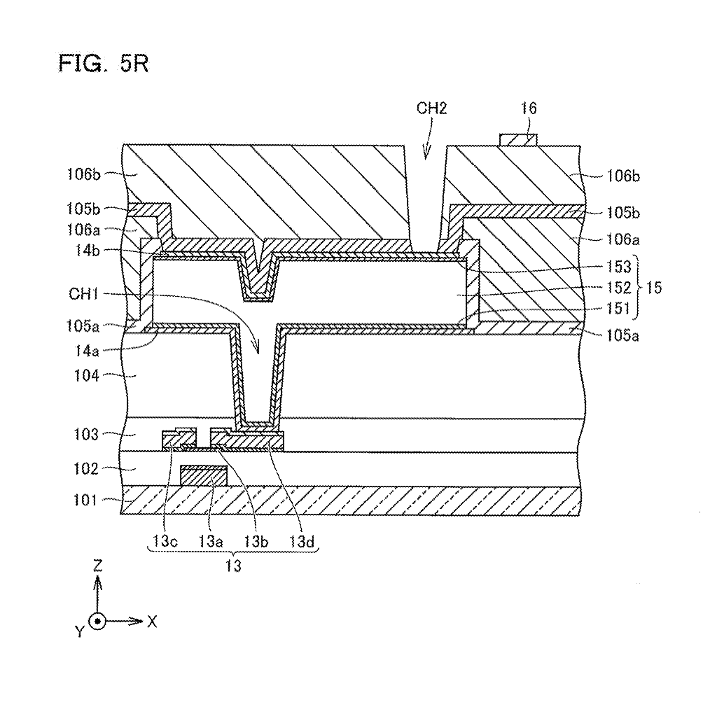

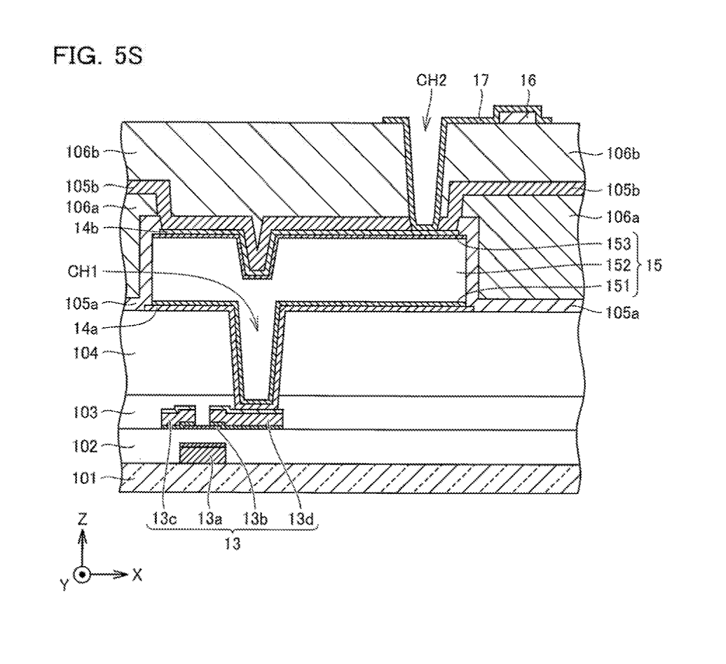

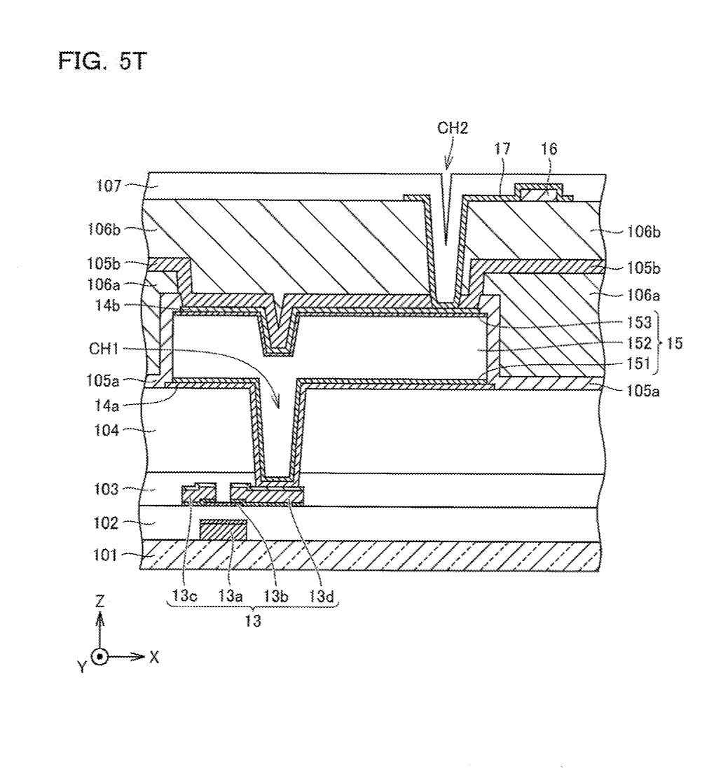

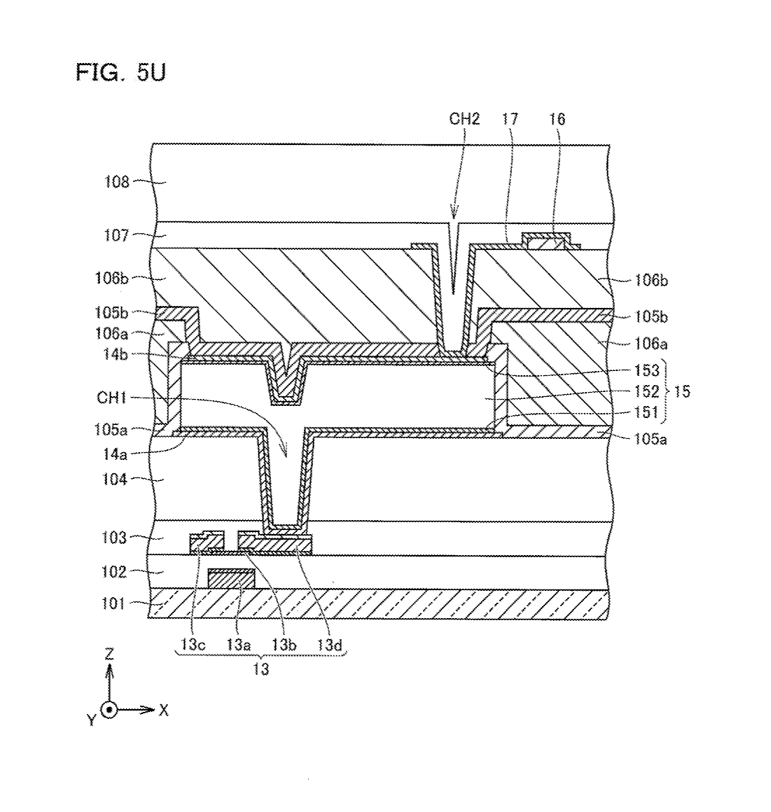

Next, the following description describes a method for producing the active matrix substrate 1 while referring to FIGS. 5A to 5U. FIGS. 5A to 5U illustrate cross-sectional views of the active matrix substrate 1 in steps of the producing process, respectively (cross sections taken along line A-A in FIG. 3).

As illustrated in FIG. 5A, the gate insulating film 102 and the TFT 13 are formed on the substrate 101 by using a known method.

Subsequently, the first insulating film 103 is formed by laminating silicon nitride (SiN) and silicon oxide (SiO₂), by using, for example, plasma CVD (see FIG. 5B).

Thereafter, a heat treatment at about 350° C. is applied to an entire surface of the substrate 101, and then, photolithography, and dry etching using fluorine-containing gas are performed, whereby the first insulating film 103 is patterned (see FIG. 5C). Through these steps, the opening 103a of the first insulating film 103 is formed above the drain electrode 13d.

Next, the second insulating film 104 made of an acrylic resin or a siloxane-based resin is formed on the first insulating film 103 by, for example, slit-coating (see FIG. 5D). Thereafter, by using photolithography, the second insulating film 104 is patterned (see FIG. 5E). Through this step, the opening 104a of the second insulating film 104 is formed on the opening 103a, whereby the contact hole CH1 composed of the opening 103a and the 104a is formed.

Subsequently, a metal film made of molybdenum nitride (MoN) is formed by, for example, sputtering, and photolithography and wet etching are carried out so that the metal film is patterned. Through these steps, the lower electrode 14a is formed on the second insulating film 104 so that the lower electrode 14a is connected with the drain electrode 13d via the contact hole CH1 (see FIG. 5F).

Next, the n-type amorphous semiconductor layer 151, the intrinsic amorphous semiconductor layer 152, and the p-type amorphous semiconductor layer 153 are formed in the stated order by using, for example, plasma CVD. Thereafter, for example, a transparent conductive film made of ITO is formed by using sputtering, and photolithography and dry etching are carried out so that the transparent conductive film is patterned. Through this step, the upper electrode 14b is formed on the p-type amorphous semiconductor layer 153 (see FIG. 5G).

Next, photolithography and dry etching are performed, whereby the n-type amorphous semiconductor layer 151, the intrinsic amorphous semiconductor layer 152, and the p-type amorphous semiconductor layer 153 are patterned (see FIG. 5H). Through this step, the photoelectric conversion layer 15 is formed.

Next, the 3a-th insulating film 105a made of silicon nitride (SiN) is formed by, for example, plasma CVD (see FIG. 5I). Thereafter, photolithography and dry etching are carried out so that the 3a-th insulating film 105a is patterned (see FIG. 5J). Through these steps, an opening H1 of the 3a-th insulating film 105a is formed on the upper electrode 14b.

In some cases, however, the etching with respect to the 3a-th insulating film 105a for forming the opening H1 causes film thinning of the upper electrode 14b, i.e., a decrease in the thickness of the top surface portion of the upper electrode 14b. In the present embodiment, therefore, it is desirable that the thickness of the upper electrode 14b when it is formed should be set with influences of the etching of the 3a-th insulating film 105a being taken into consideration.

Subsequently, the 4a-th insulating film 106a made of, for example, an acrylic resin or a siloxane-based resin is formed by slit-coating (see FIG. 5K). Thereafter, by using photolithography, the 4a-th insulating film 106a is patterned (see FIG. 5L). Through these steps, an opening H2 of the 4a-th insulating film 106a, which has an opening width greater than that of the opening H1, is formed on the opening H1 of the 3a-th insulating film 105a.

Subsequently, the 3b-th insulating film 105b made of silicon nitride (SiN) is formed by, for example, plasma CVD, so as to cover the 4a-th insulating film 106a (see FIG. 5M). Thereafter, photolithography and dry etching are carried out so that the 3b-th insulating film 105b is patterned (see FIG. 5N). Through these steps, an opening H3 of the 3b-th insulating film 105b is formed on the upper electrode 14b.

Next, for example, the 4b-th insulating film 106b made of an acrylic resin or a siloxane-based resin is formed by slit-coating so as to cover the 3b-th insulating film 105b (see FIG. 5O), and the 4b-th insulating film 106b is patterned by using photolithography (see FIG. 5P). Through these steps, an opening H4 of the 4b-th insulating film 106b is formed on the opening H3 of the 3b-th insulating film 105b, whereby the contact hole CH2, composed of the openings H3 and H4, is formed.

Subsequently, a metal film 160 is formed by laminating molybdenum nitride (MoN), aluminum (Al), and titanium (Ti) in the stated order, by, for example, sputtering (see FIG. 5Q). Thereafter, photolithography and wet etching are carried out so that the metal film 160 is patterned (see FIG. 5R). For wet etching of the metal film 160, for example, an etchant containing acetic acid, nitric acid, and phosphoric acid is used. Through these steps, the bias line 16 is formed on the fourth insulating film 106.

Next, a transparent conductive film made of ITO is formed by, for example, sputtering, and then, photolithography and dry etching are carried out so that the transparent conductive film is patterned. Through these steps, the transparent conductive film 17 is formed that is connected with the bias line 16 and is connected with the photoelectric conversion layer 15 via the contact hole CH2 (see FIG. 5S).

Subsequently, the fifth insulating film 107 made of silicon nitride (SiN) is formed on the 4b-th insulating film 106b so as to cover the transparent conductive film 17, by, for example, plasma CVD (see FIG. 5T).

Next, the sixth insulating film 108 made of an acrylic resin or a siloxane-based resin is formed so as to cover the fifth insulating film 107 by, for example, slit-coating (see FIG. 5U). Through this process, the active matrix substrate 1 of the present embodiment is produced.

In the active matrix substrate 1 of the present embodiment, side surfaces of the photodiode 12 are covered with the 3a-th insulating film 105a, the top surface of the upper electrode 14b is covered with the 3b-th insulating film 105b, and further, the 3a-th insulating film 105a and the 3b-th insulating film 105b are in contact with each other on the upper electrode 14b. Besides, outside the photodiode 12, the 3a-th insulating film 105a is covered with the 4a-th insulating film 106a and the 3b-th insulating film 105b. In other words, the side surfaces of the photodiode 12 are covered with the 3a-th insulating film 105a, the 4a-th insulating film 106a, and the 3b-th insulating film 105b.

The 3a-th insulating film 105a and the 3b-th insulating film 105b, which are inorganic insulating films, have higher waterproofness than that of the 4a-th insulating film 106a and the 4b-th insulating film 106b, which are resin films. Accordingly, in a case where moisture permeates the 4b-th insulating film 106b through a scar occurring to the surface of the active matrix substrate 1, even with any discontinuous part being present in the 3a-th insulating film 105a covering the side surfaces of the photodiode 12, moisture can be prevented by the 3b-th insulating film 105b from penetrating through the discontinuous part in the 3a-th insulating film 105a. As a result, the discontinuous part of the 3a-th insulating film 105a does not serve as a leakage path for leakage current of the photodiode 12, and hence, this makes it possible to reduce deterioration of the X-ray detection accuracy caused by leakage current.

In the above-described step in FIG. 5J, the 3a-th insulating film 105a is patterned by using photolithography so that the opening H1 of the 3a-th insulating film 105a is formed, but this step may be carried out as follows. For example, after the 4a-th insulating film 106a is formed on the 3a-th insulating film 105a, the 3a-th insulating film 105a is patterned by using the 4a-th insulating film 106a as a mask so that the opening H1 of the 3a-th insulating film 105a is formed. Further, in the above-described step in FIG. 5N, the 3b-th insulating film 105b is patterned by using photolithography so that the opening H3 of the 3b-th insulating film 105b is formed, but this step may be as follows instead. For example, after the 3b-th insulating film 105b is formed in the step in FIG. 5M, the 4b-th insulating film 106b is formed on the 3b-th insulating film 105b. Thereafter, patterning is carried out by using the 4b-th insulating film 106b as a mask so that the opening H3 of the 3b-th insulating film 105b is formed.

### (Operation of X-Ray Imaging Device 100)

Here, operations of the X-ray imaging device 100 illustrated in FIG. 1 are described. First, X-rays are emitted from the X-ray source 3. Here, the control unit 2 applies a predetermined voltage (bias voltage) to the bias line 16 (see FIG. 3 and the like). X-rays emitted from the X-ray source 3 transmit an object S, and are incident on the scintillator 4. The X-rays incident on the scintillator 4 are converted into fluorescence (scintillation light), and the scintillation light is incident on the active matrix substrate 1. When the scintillation light is incident on the photodiode 12 provided in each pixel in the active matrix substrate 1, the scintillation light is changed to charges by the photodiode 12 in accordance with the amount of the scintillation light. A signal according to the charges obtained by conversion by the photodiode 12 is read out through the source line 10 to the signal reading unit 2B (see FIG. 2 and the like) when the TFT 13 (see FIG. 3 and the like) is in the ON state according to a gate voltage (positive voltage) that is output from the gate control unit 2A through the gate line 11. Then, an X-ray image in accordance with the signal thus read out is generated in the control unit 2.

### Embodiment 2

Embodiment 1 is described above with reference to an example in which, outside the photodiode 12, the 3a-th insulating film 105a, the 4a-th insulating film 106a, and the 3b-th insulating film 105b are extended to the photodiode 12 of the adjacent pixel. In this case, if not only the surface of the active matrix substrate 1 has scars, but also the 3b-th insulating film 105b has a discontinuous part, a scar, or the like, there is a possibility that moisture would penetrate from the scar or the like of the 3b-th insulating film 105b to the 4a-th insulating film 106a. If moisture permeates the 4a-th insulating film 106a, moisture gets in the discontinuous part of not only the 3a-th insulating film 105a covering side surfaces of the photodiode 12 of a certain one of the pixels, but also in the 3a-th insulating film 105a covering side surfaces of the photodiode 12 of another pixel adjacent thereto. In other words, a leakage path is formed in side surfaces of the photodiodes 12 of a plurality of the pixels, whereby a range in which leakage current flows is extended.

The following description describes the present embodiment in which the extension of a leakage path is reduced even if moisture penetrates from the 3b-th insulating film 105b.

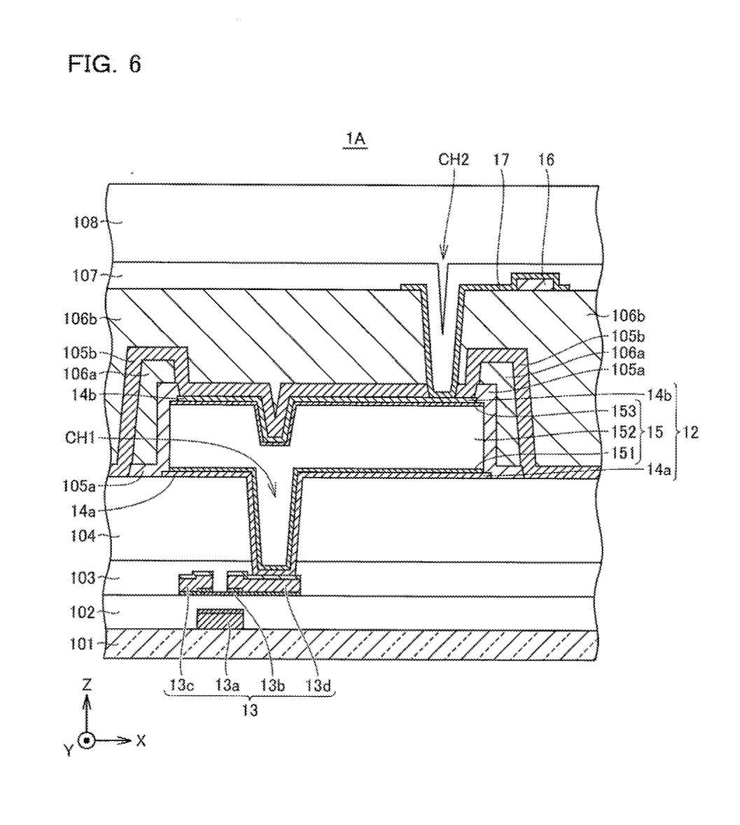

FIG. 6 is a cross-sectional view of the pixel part of the active matrix substrate in the present embodiment. In FIG. 68, members identical to those in Embodiment 1 are denoted by the same reference symbols as those in Embodiment 1. The following description principally describes configurations different from those in Embodiment 1.

As illustrated in FIG. 6, in the active matrix substrate 1A, a part of the 3a-th insulating film 105a that is in contact with the second insulating film 104 has a length smaller than that in Embodiment 1. The 4a-th insulating film 106a is provided exclusively on the 3a-th insulating film 105a.

Outside the photodiode 12, the 3b-th insulating film 105b is provided on the second insulating film 104 so as to cover the 4a-th insulating film 106a and the 3a-th insulating film 105a. The 3b-th insulating film 105b is in contact with the 3a-th insulating film 105a not only on the upper electrode 14b, but also on the second insulating film 104.

In other words, in the present embodiment, the 3b-th insulating film 105b outside the photodiode 12 is extended to an adjacent pixel, but the 3a-th insulating films 105a corresponding to adjacent ones of the pixels are divided and separated from each other, and so are the 4a-th insulating films 106a corresponding to adjacent ones of the pixels.

In this way, in the present embodiment, the 3a-th insulating film 105a and the 4a-th insulating film 106a are not extended to an adjacent pixel. Even if moisture permeates the 4a-th insulating film 106a of a certain pixel, the moisture therefore does not penetrate to the 4a-th insulating film 106a of a pixel adjacent to the foregoing pixel, whereby the extension of leakage path can be prevented.

Incidentally, in this case, it is likely that moisture would penetrate through a discontinuous part of the 3a-th insulating film 105a covering side surfaces of the photodiode 12 of the pixel in which moisture has permeated the 4a-th insulating film 106a, and this 3a-th insulating film 105a serves as a leakage path through which leakage current flows. But if there is no scar or the like in the 3b-th insulating film 105b, the 3b-th insulating film 105b prevents moisture from getting into the discontinuous part of the 3a-th insulating film 105a, and no leakage path is formed, as is the case with Embodiment 1.

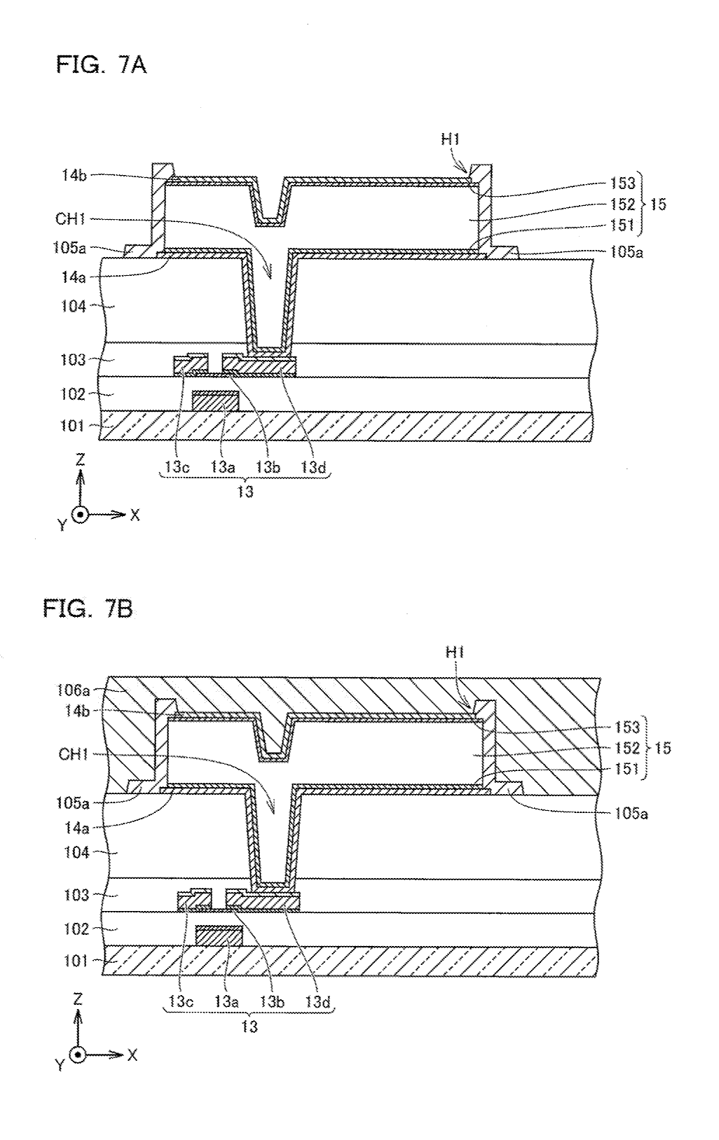

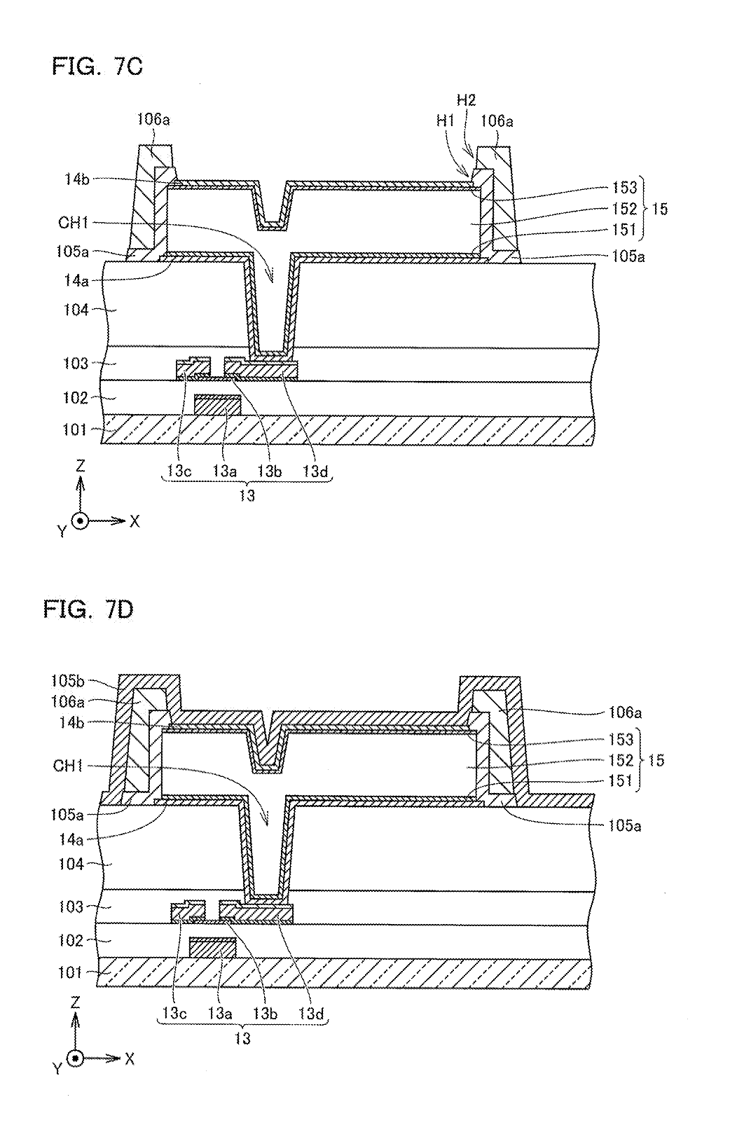

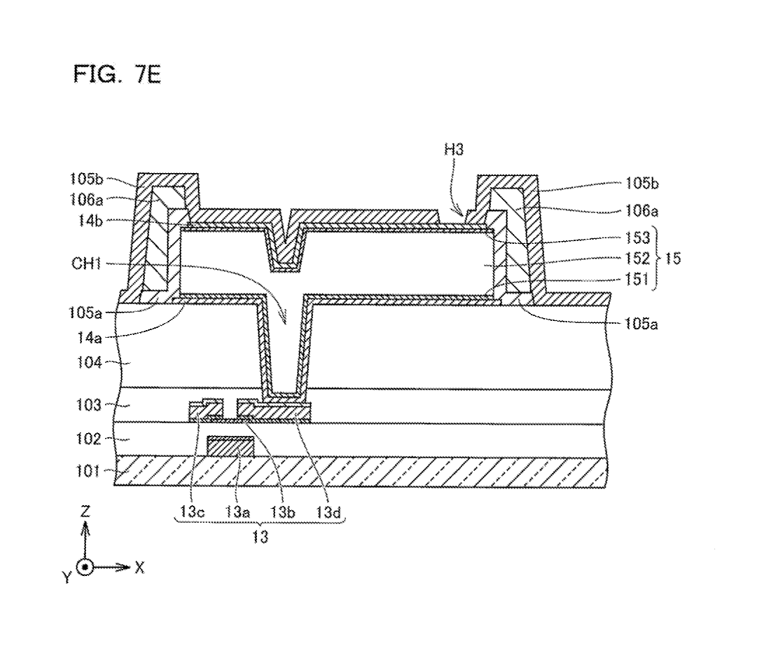

The active matrix substrate 1A in the present embodiment is produced through the following process. More specifically, after the above-described steps illustrated in FIGS. 5A to 5I are performed, photolithography and dry etching are carried out in the state illustrated in FIG. 5I so that the 3a-th insulating film 105a is patterned. Here, the 3a-th insulating film 105a in contact with the second insulating film 104 is etched so that the opening H1 of the 3a-th insulating film 105a is formed, and at the same time, the 3a-th insulating films 105a of adjacent ones of the pixels are separated from each other (see FIG. 7A).

Subsequently, in the same manner as that in the step illustrated in FIG. 5K, the 4a-th insulating film 106a is formed so as to cover the 3a-th insulating film 105 (see FIG. 7B), and thereafter, the 4a-th insulating film 106a is patterned by using photolithography (see FIG. 7C). Through these steps, the 4a-th insulating film 106a is formed exclusively on the 3a-th insulating film 105a, and the opening H2 of the 4a-th insulating film 106a, having a width greater than that of the opening H1, is formed.

Subsequently, in the same manner as that in the step illustrated in FIG. 5M, the 3b-th insulating film 105b is formed so as to cover the 4a-th insulating film 106a (see FIG. 7D), and photolithography and dry etching are carried out so that the 3b-th insulating film 105b is patterned (see FIG. 7E). Through these steps, the 3a-th insulating film 105a and the 3b-th insulating film 105b are connected inside and outside the photodiode 12, and the opening H3 of the 3b-th insulating film 105b is formed on the upper electrode 14b. Thereafter, steps identical to the above-described steps illustrated in FIGS. 5O to 5U are carried out, whereby the active matrix substrate 1A is produced.

### Embodiment 3

Embodiment 1 is described above with reference to an exemplary configuration in which the side surface portions of the photodiode 12 are covered with the 3a-th insulating film 105a, and the top surface of the upper electrode 14b except for the portion thereof where the contact hole CH2 is formed is covered with the 3b-th insulating film 105b. In this case, when the 3a-th insulating film 105a is pattered, the top surface of the upper electrode 14b is affected by etching, film thinning occurs to the top surface portion of the upper electrode 14b, i.e., the thickness of the top surface portion of the upper electrode 14b decreases. As the present embodiment, an exemplary configuration is described in which the formation of a leakage path at the side surfaces of the photodiode 12 is prevented, without film thinning occurring to the upper electrode 14b.

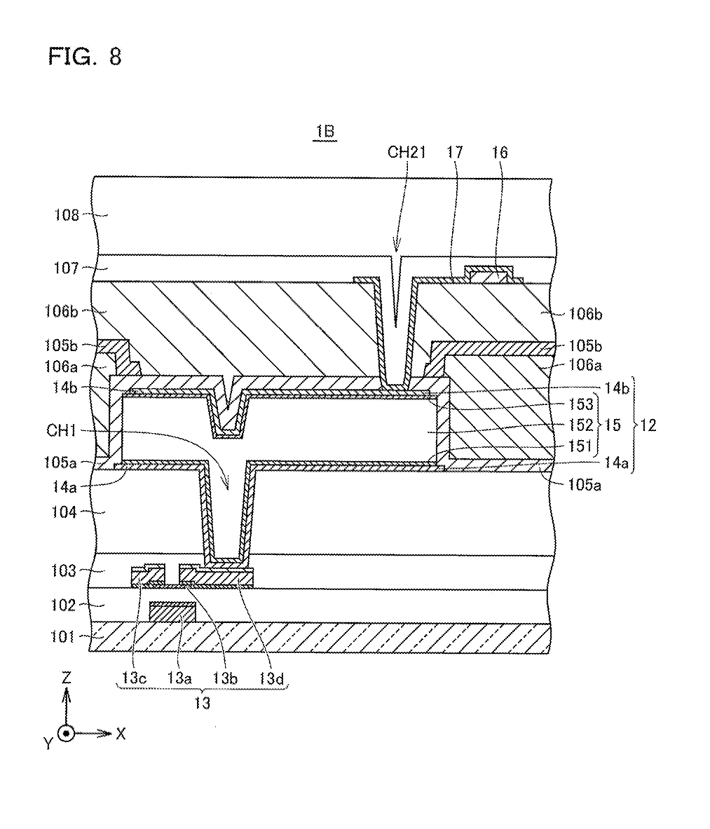

FIG. 8 is a cross-sectional view illustrating a pixel part of an active matrix substrate in the present embodiment. In FIG. 8, members identical to those in Embodiment 1 are denoted by the same reference symbols as those in Embodiment 1. The following description principally describes configurations different from those in Embodiment 1.

As illustrated in FIG. 8, in an active matrix substrate 1B, the 3a-th insulating film 105a covers the surfaces of the photodiode 12 except for a part of the top surface of the photodiode 12. In other words, the 3a-th insulating film 105a is divided and separated on the top surface of the upper electrode 14b, and cover the side surfaces of the photodiode 12. The 3a-th insulating film 105a on the second insulating film 104 is extended to the adjacent pixel.

The 4a-th insulating film 106a is provided so as to cover the 3a-th insulating film 105a outside the photodiode 12, and is extended to the adjacent pixel.

The 3b-th insulating film 105b is provided so as to be in contact with the 3a-th insulating film 105a inside the photodiode 12, and to cover the 4a-th insulating film 106a inside the photodiode 12. In other words, the 3b-th insulating film 105b covers the side surfaces of the photodiode 12 with the 3a-th insulating film 105a and the 4a-th insulating film 106a being interposed therebetween.

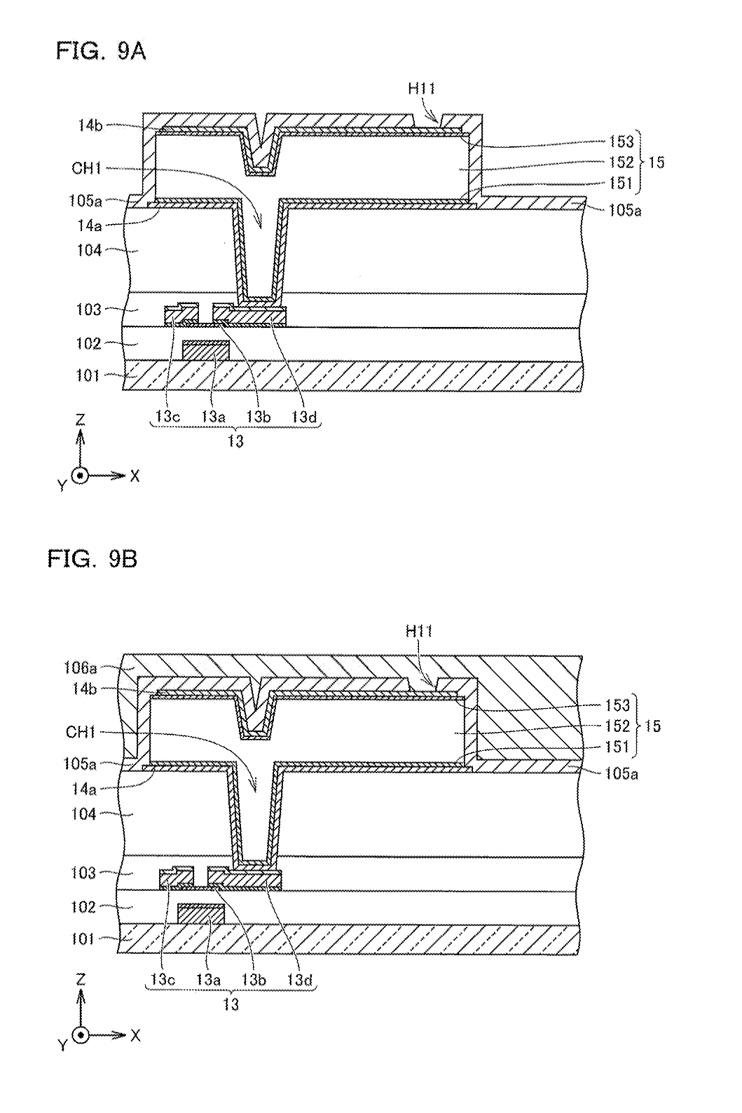

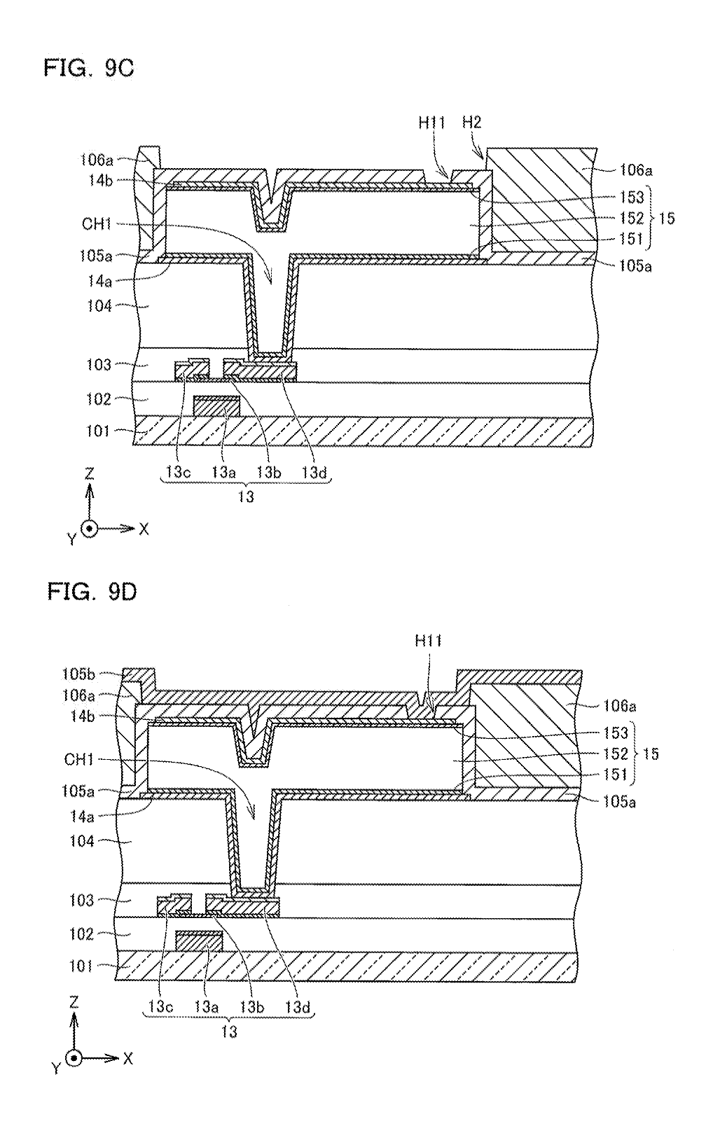

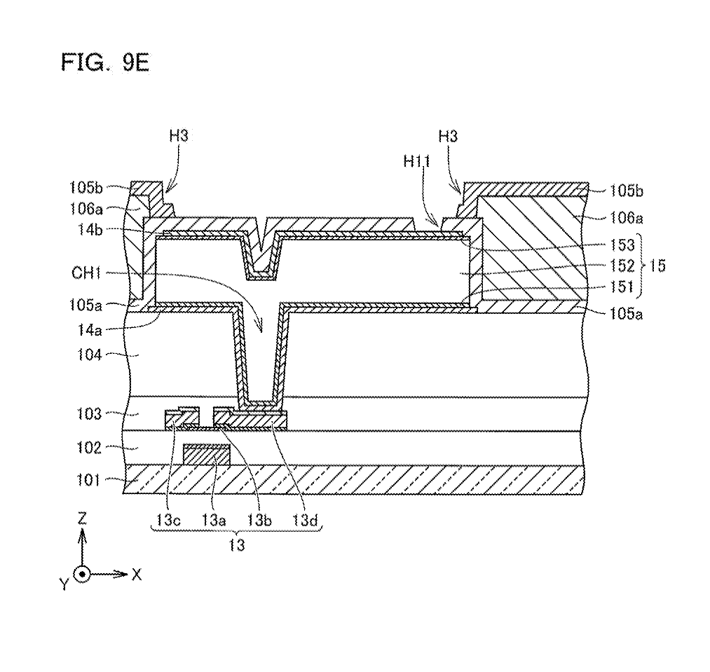

The production of the active matrix substrate B in the present embodiment is performed as follows. In the present embodiment, after steps identical to those described above with reference to FIGS. 5A to 5I are carried out, photolithography and dry etching are carried out so that the 3a-th insulating film 105a is patterned (see FIG. 9A). Through these steps, an opening H11 of the 3a-th insulating film 105a is formed on the upper electrode 14b. The opening H11 has a width smaller than that of the opening H1 of the 3a-th insulating film 105a in Embodiment 1 described above, and therefore, the area of the top surface of the upper electrode 14b covered with the 3a-th insulating film 105a is larger than that in Embodiment 1. It is therefore less likely that film thinning would be caused to the top surface of the upper electrode 14b by the etching of the 3a-th insulating film 105a.

After the step illustrated in FIG. 9A, the 4a-th insulating film 106a is formed in the same manner as that of the step illustrated in FIG. 5K so as to cover the 3a-th insulating film 105a (see FIG. 9B), and thereafter, by using photolithography, 4a-th insulating film 106a is patterned (see FIG. 9C). Through these steps, the 4a-th insulating film 106a covering the 3a-th insulating film 105a is formed outside the photodiode 12, and the opening H2 of the 4a-th insulating film 106a, having a width greater than that of the opening H11, is formed.

Subsequently, in the same manner as that in the step illustrated in FIG. 5M, the 3b-th insulating film 105b is formed so as to cover the 4a-th insulating film 106a (see FIG. 9D), and photolithography and dry etching are carried out so that the 3b-th insulating film 105b is patterned (see FIG. 9E). Through these steps, on the 3a-th insulating film 105a, an opening H3 of the 3b-th insulating film 105b is formed, outside the opening H11.

Thereafter, in the same manner as that in the above-described step illustrated in FIG. 5O, the 4b-th insulating film 106b covering the 3a-th insulating film 105a and the 3b-th insulating film 105b is formed, a contact hole CH21 composed of the opening H11 and the opening H4 of the 4b-th insulating film 106b (see FIG. 8) is formed using the same manner as that in FIG. 5P described above. Subsequently, steps identical to the above-described steps illustrated in FIGS. 5O to 5U are carried out, whereby the active matrix substrate 1B is produced.

### Embodiment 41

Embodiment 3 is described above with reference to an exemplary configuration in which the 4a-th insulating film 106a is extended to the photodiode 12 of the adjacent pixel outside the photodiode 12. In this case, if the 3b-th insulating film 105b has a discontinuous part, a scar, or like as described above in conjunction with Embodiment 2, moisture penetrates through this part to the 4a-th insulating film 106a, and a leakage path is formed in the 3a-th insulating film 105a that covers side surfaces of the photodiodes 12 of a plurality of pixels. As the present embodiment, an exemplary configuration is described in which the extension of a leakage path is prevented even if moisture penetrates from the 3b-th insulating film 105b in the structure of Embodiment 3.

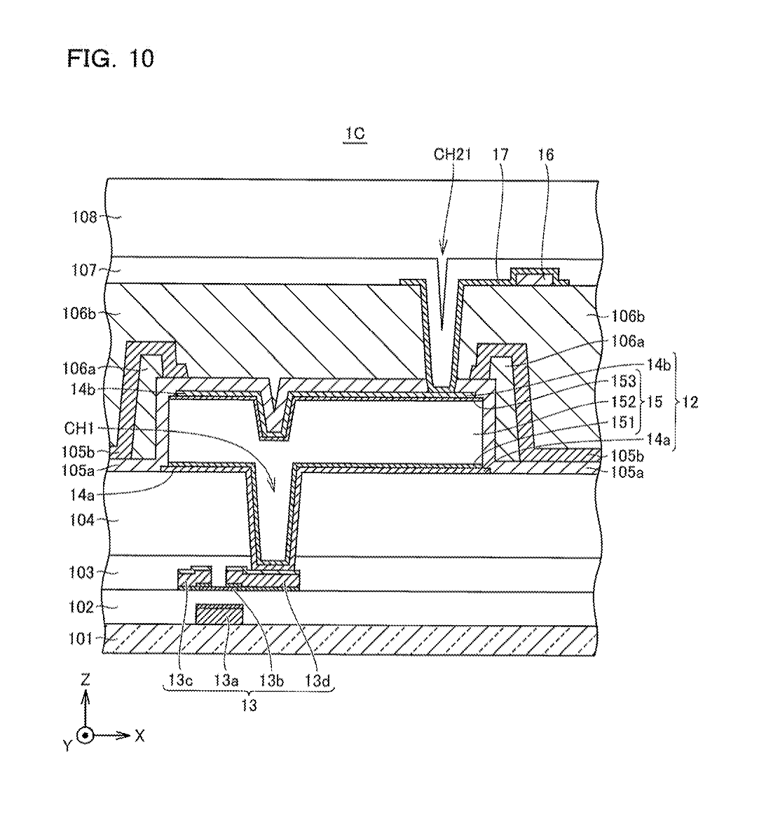

FIG. 10 is a cross-sectional view illustrating a pixel part of an active matrix substrate in the present embodiment. In FIG. 10, members identical to those in Embodiment 3 are denoted by the same reference symbols as those in Embodiment 3. The following description principally describes configurations different from those in Embodiment 3.

As illustrated in FIG. 10, in an active matrix substrate 1C, the 3a-th insulating film 105a and the 3b-th insulating film 105b are in contact with each other in a part area of the top surface on the photodiode 12 and an area outside the photodiode 12, and the 4a-th insulating film 106a is provided in an area outside the photodiode 12, interposed between the 3a-th insulating film 105a and the 3b-th insulating film 105b. In other words, the 4a-th insulating film 106a is not extended to the adjacent pixel outside the photodiode 12, and is separated between adjacent ones of the pixels. Accordingly, even if moisture penetrating from a discontinuous part, a scar, or the like occurring to the 3b-th insulating film 105b permeates the 4a-th insulating film 106a, the permeation of the moisture into the 4a-th insulating film 106a of the adjacent pixel is prevented, and the leakage path is not extended to the 3a-th insulating film 105a of the foregoing pixel.

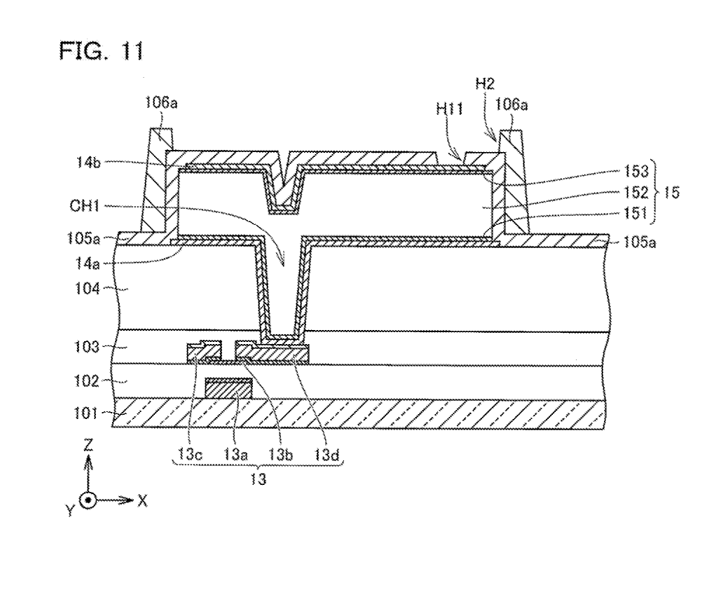

The production of the active matrix substrate 1C in the present embodiment is performed as follows. After the above-described step illustrated in FIG. 9B, the 4a-th insulating film 106a is patterned by using photolithography (see FIG. 11). Through this step, the 4a-th insulating film 106a is formed that has the opening H2 on an outer side with respect to the opening H11 of the 3a-th insulating film 105a, overlaps with a part of the 3a-th insulating film 105a that covers side surfaces of the photodiode 12, and is divided and separated between adjacent ones of the pixels. Thereafter, steps identical to the above-described steps illustrated in FIG. 9D and the subsequent drawings are carried out, whereby the active matrix substrate 1C is produced.

### Embodiment 5

Embodiment 3 is described above with reference to an exemplary configuration in which the 3b-th insulating film 105b is not provided on the top surface of the upper electrode 14b, but the 3a-th insulating film 105a and the 3b-th insulating film 105b may be provided on the top surface of the upper electrode 14b in an overlapping state. The following description describes the configuration in this case more specifically.

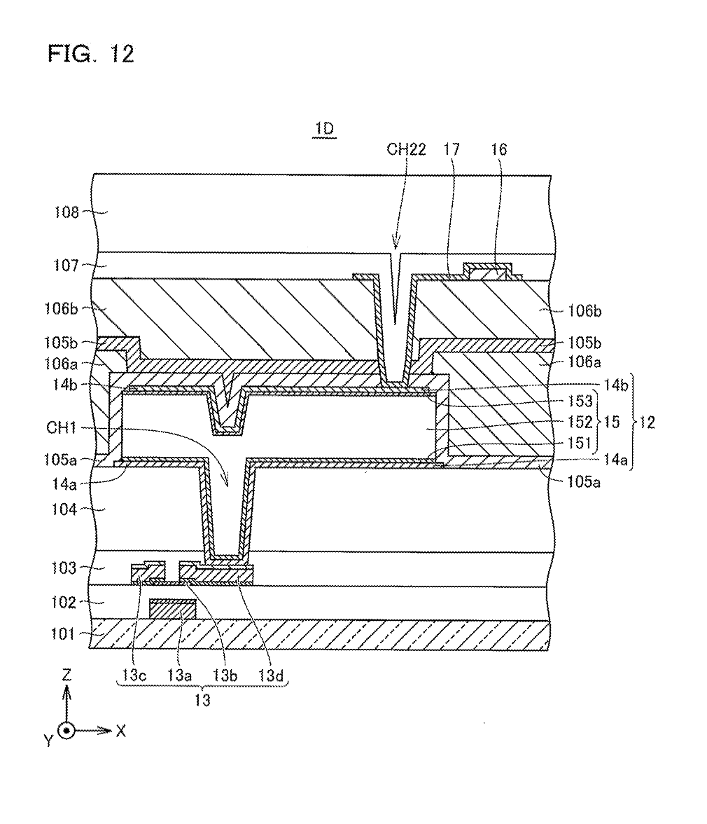

FIG. 12 is a cross-sectional view illustrating a pixel part of an active matrix substrate in the present embodiment. In FIG. 12, members identical to those in Embodiment 3 are denoted by the same reference symbols as those in Embodiment 3. The following description principally describes configurations different from those in Embodiment 3.

As illustrated in FIG. 12, in the active matrix substrate 1D, the 3b-th insulating film 105b overlaps with the 3a-th insulating film 105a provided on the top surface of the upper electrode 14b, and outside the photodiode 12, the 3b-th insulating film 105b is provided on the 4a-th insulating film 106a. In other words, outside the photodiode 12, the 3a-th insulating film 105a and the 3b-th insulating film 105b overlap with each other with the 4a-th insulating film 106a being interposed therebetween.

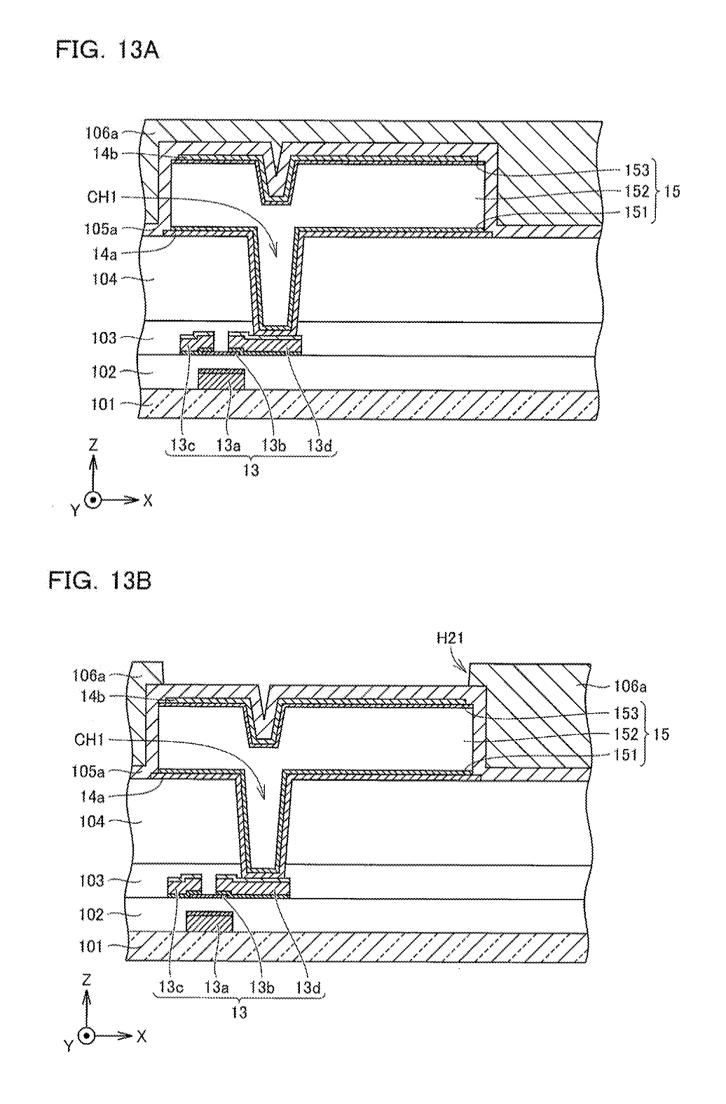

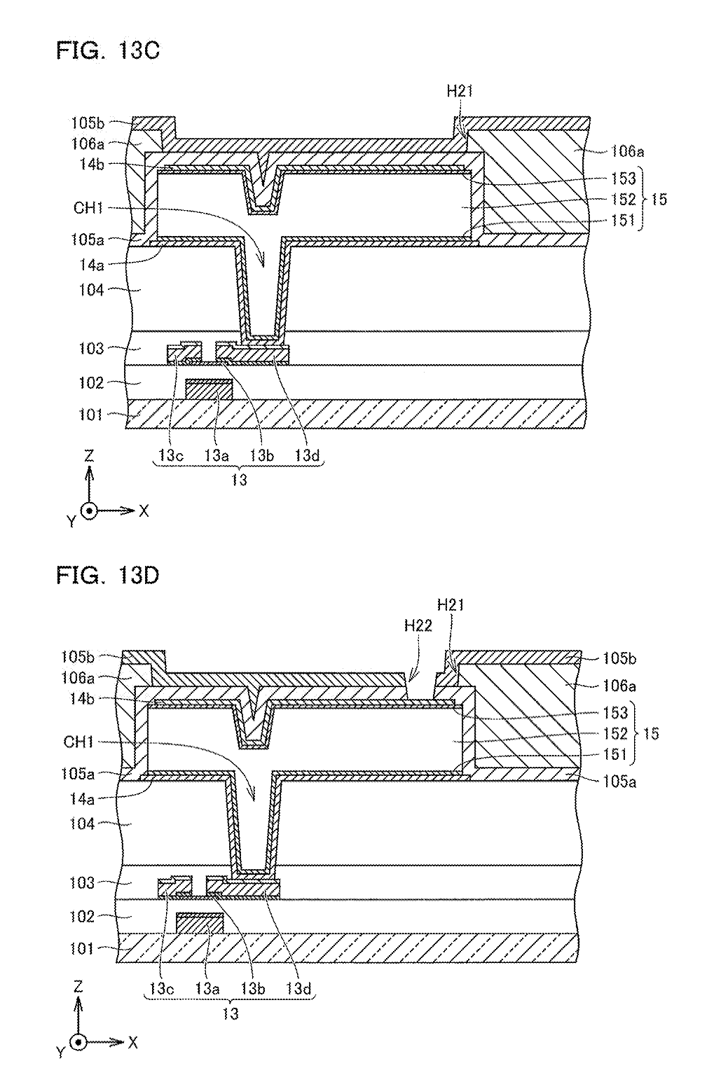

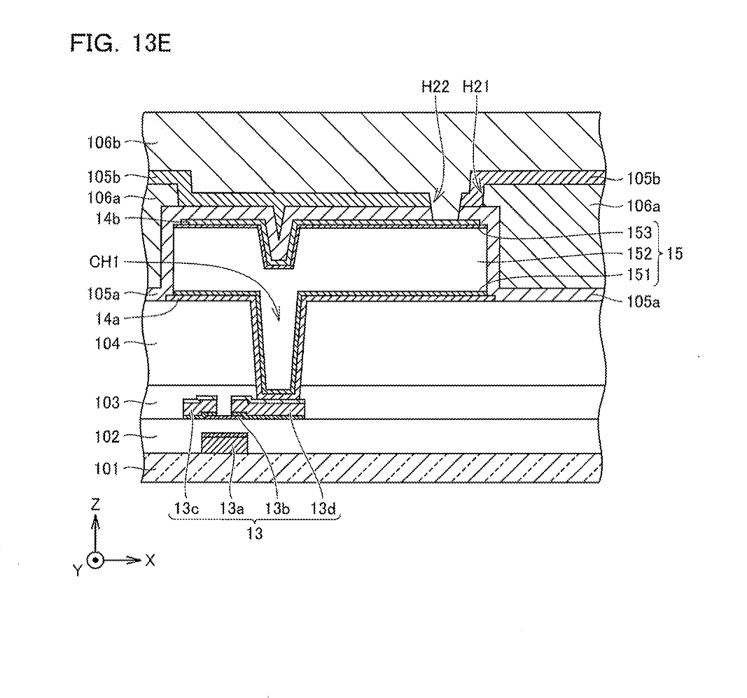

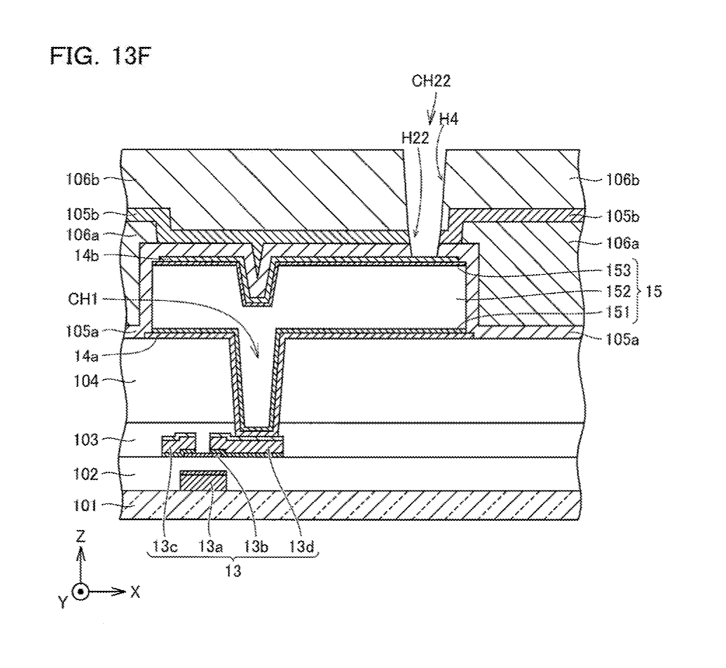

The production of the active matrix substrate 1D is performed as follows. Steps identical to those described above with reference to FIGS. 5A to 5I are carried out, and thereafter, the 4a-th insulating film 106a made of an acrylic resin or a siloxane-based resin is formed by, for example, slit-coating (see FIG. 13A). Subsequently, by using photolithography, the 4a-th insulating film 106a is patterned (see FIG. 13B). Through these steps, the opening H21 of the 4a-th insulating film 106a is formed on the 3a-th insulating film 105a, on a part area of the top surface on the photodiode 12.

Next, by a step identical to that illustrated in FIG. 5M, the 3b-th insulating film 105b is formed so as to cover the 4a-th insulating film 106a (see FIG. 13C), and then, photolithography and dry etching are carried out so that the 3a-th insulating film 105a and the 3b-th insulating film 105b are patterned (see FIG. 13D). Through these steps, an opening H22 passing through the 3a-th insulating film 105a and the 3b-th insulating film 105b is formed on the upper electrode 14b.

Subsequently, by a method identical to the above-described method illustrated in FIG. 5O, the 4b-th insulating film 106b covering the 3b-th insulating film 105b is formed (see FIG. 13E), and then, by using a method identical to the above-described method illustrated in FIG. 5P, the opening H4 of the 4b-th insulating film 106b is formed on the opening H22, whereby a contact hole CH22 composed of the opening H22 and the opening H4 is formed (see FIG. 13F). Thereafter, steps identical to the above-described steps illustrated in FIGS. 5Q to 5U are carried out, whereby the active matrix substrate 1D is produced.

Incidentally, in this example, in FIG. 13D, the 3a-th insulating film 105a and the 3b-th insulating film 105b are patterned by using photolithography, but the process may be as follows instead: after the 3b-th insulating film 105b is formed, the 4b-th insulating film 106b is formed, and the 3a-th insulating film 105a and the 3b-th insulating film 105b are patterned by using the 4b-th insulating film 106b as a mask, whereby the opening H22 is formed.

In the present embodiment, the 3b-th insulating film 105b is formed so as to overlap with the 3a-th insulating film 105a on the top surface of the upper electrode 14b. Further, both of the 3a-th insulating film 105a and the 3b-th insulating film 105b are simultaneously patterned so that the opening H22 passing through the 3a-th insulating film 105a and the 3b-th insulating film 105b is formed. It is therefore unlikely that film thinning would occur to the 3a-th insulating film 105a due to the patterning, as compared with Embodiments 3 and 4 mentioned above, and it is unlikely that film thinning would occur to the top surface of the upper electrode 14b due to the patterning, as compared with Embodiments 1 and 2 mentioned above.

Further, in the present embodiment, when moisture permeates the 4b-th insulating film 106b through a scar or the like on the surface of the active matrix substrate 1D, even with any discontinuous part being present in the 3a-th insulating film 105a covering the side surfaces of the photodiode 12, permeation of moisture into the 3a-th insulating film 105a can be prevented by the 3b-th insulating film 105b. As a result, a discontinuous part of the 3a-th insulating film 105a does not serve as a leakage path, it is unlikely that the X-ray detection accuracy would degrade due to leakage current.

### Embodiment 6

In Embodiment 5 described above, outside the photodiode 12, the 4a-th insulating film 106a is extended to the photodiode 12 of the adjacent pixel, but for preventing the extension of a leakage path, the 4a-th insulating film 106a may be divided and separated between the photodiodes 12 of adjacent ones of the pixels. The following description describes a configuration of an active matrix substrate in this case.

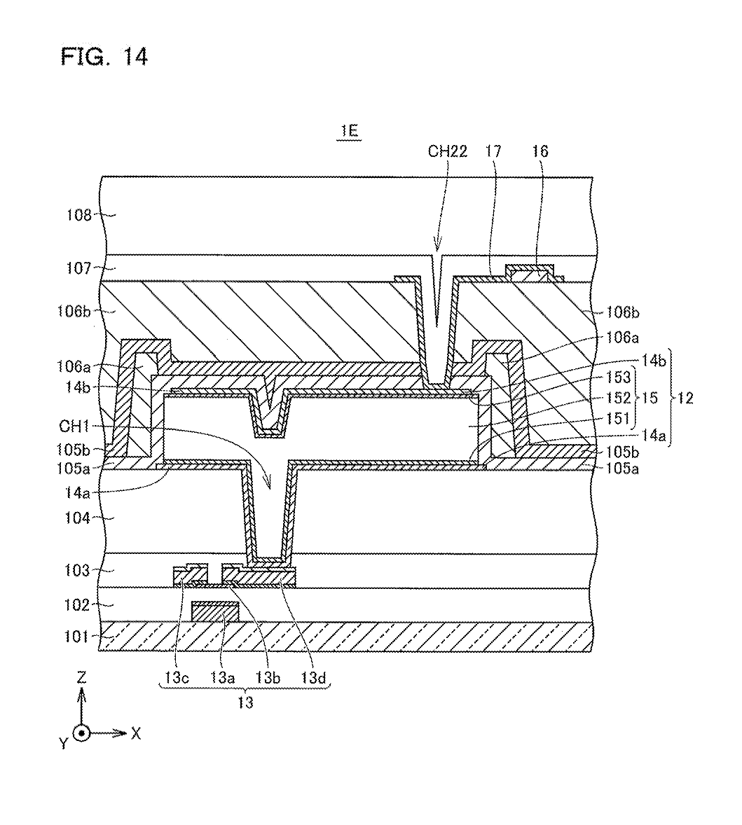

FIG. 14 is a cross-sectional view of a pixel part of an active matrix substrate in the present embodiment. In FIG. 14, members identical to those in Embodiment 5 are denoted by the same reference symbols as those in Embodiment 5. The following description principally describes configurations different from those in Embodiment 5.

As illustrated in FIG. 14, in an active matrix substrate 1E in the present embodiment, the 3a-th insulating film 105a and the 3b-th insulating film 105b are in contact with each other outside the photodiode 12, and the 4a-th insulating film 106a is provided between the 3a-th insulating film 105a and the 3b-th insulating film 105b, outside the photodiode 12. In other words, the 4a-th insulating film 106a is not extended to the adjacent pixel, and is separated between adjacent ones of the pixels.

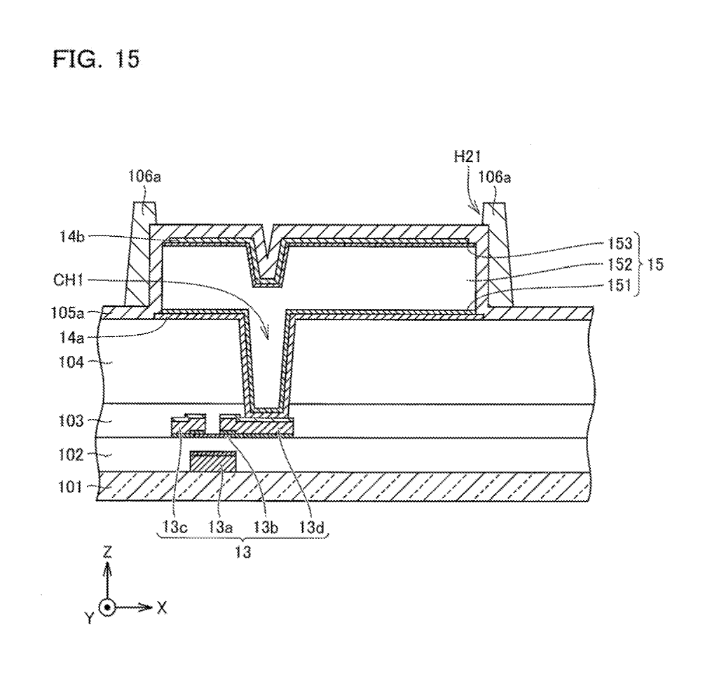

The production of the active matrix substrate 1E in the present embodiment is performed as follows. In other words, after the above-described step illustrated in FIG. 13A, the 4a-th insulating film 106a is patterned by using photolithography (see FIG. 15). Through this step, the 4a-th insulating film 106a other than portions thereof covering the side surfaces of the photodiode 12, on the 3a-th insulating film 105a, is removed. As a result, the 4a-th insulating film 106a overlaps with the 3a-th insulating film 105a provided on the side surfaces of the photodiode 12, and is positioned apart from another 4a-th insulating film 106a of the adjacent pixel. Thereafter, steps identical to the above-described steps illustrated in FIG. 13C and the subsequent drawings are carried out, whereby the active matrix substrate 1E is produced.

With such a configuration, even if moisture penetrating from a discontinuous part, a scar, or the like occurring to the 3b-th insulating film 105b permeates the 4a-th insulating film 106a, the permeation of the moisture into the 4a-th insulating film 106a of the adjacent pixel is prevented, and the leakage path is not extended to the 3a-th insulating film 105a of the foregoing pixel.

### Embodiment 7

Embodiments 1 and 3 are described above with reference to an exemplary configuration in which the 4a-th insulating film 106a is provided between the 3a-th insulating film 105a and the 3b-th insulating film 105b outside the photodiode 12, but the structure may be such that the 4a-th insulating film 106a is not provided. The following description describes modification examples of Embodiment 1 and Embodiment 3 having a structure in which the 4a-th insulating film 106a is not provided.

### (7-1) Modification Example of Embodiment 1

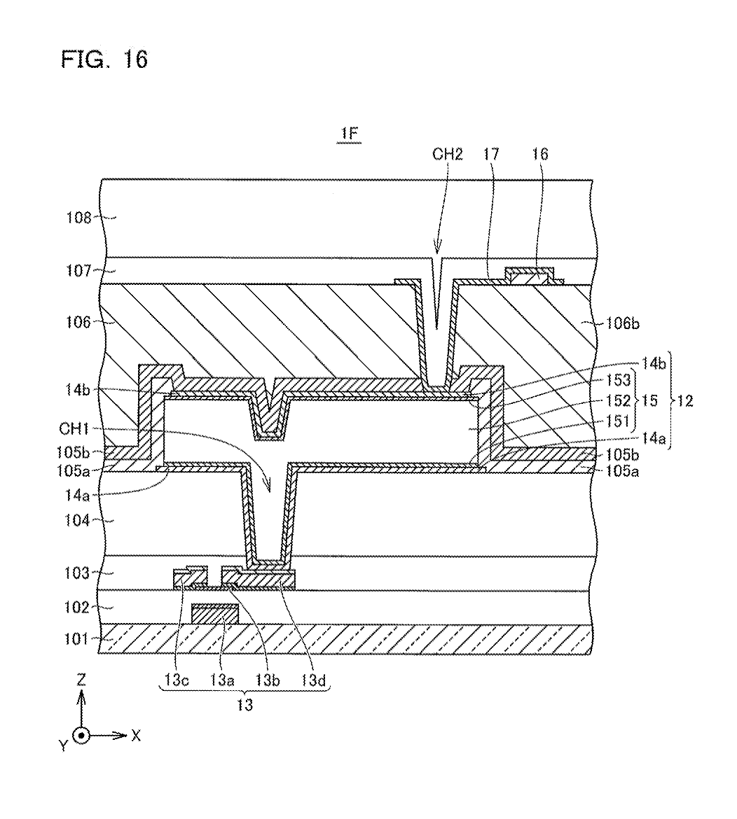

FIG. 16 is a cross-sectional view of a pixel part in Embodiment 1 having a structure in which the 4a-th insulating film 106a is not provided. In FIG. 16, members identical to those in Embodiment 1 are denoted by the same reference symbols as those in Embodiment 1. The following description principally describes configurations different from those in Embodiment 1.

As illustrated in FIG. 16, in an active matrix substrate 1F, the 3b-th insulating film 105b is arranged so as to overlap with the 3a-th insulating film 105a covering the side surfaces of the photodiode 12. In other words, outside the photodiode 12, the 3b-th insulating film 105b overlaps with the 3a-th insulating film 105a.

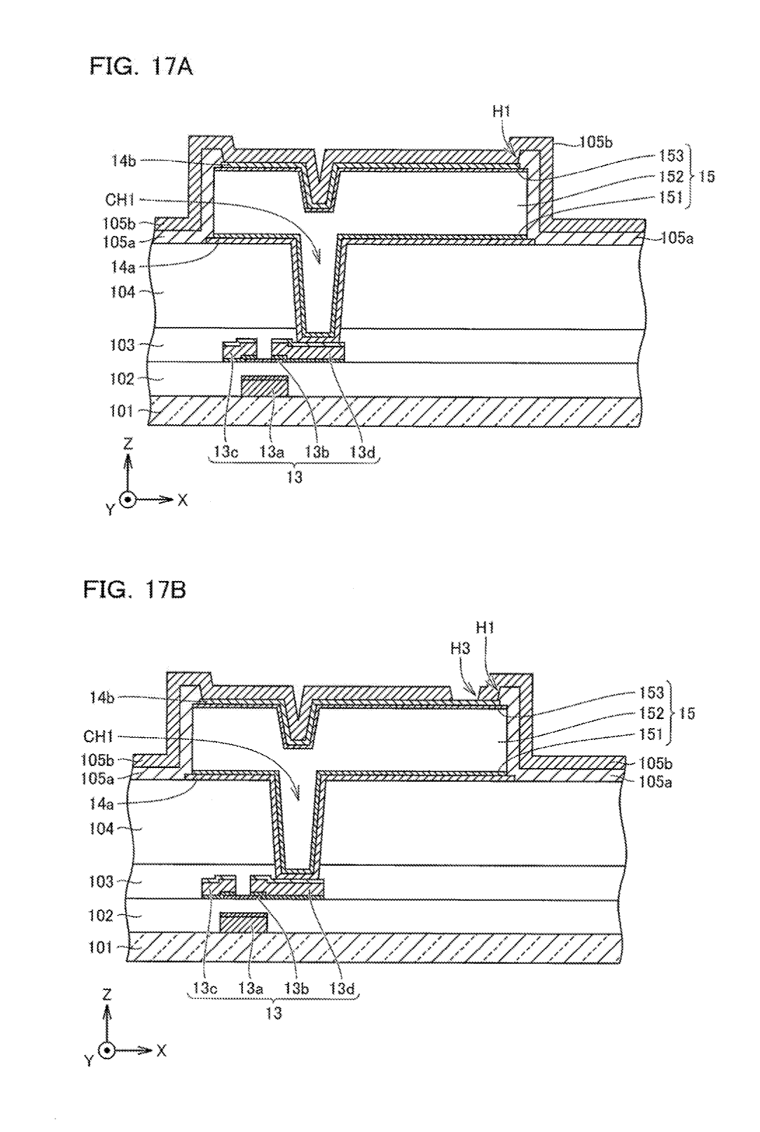

The production of the active matrix substrate 1F is performed as follows. First, steps identical to the above-described steps illustrated in FIGS. 5A to 5J are carried out, and thereafter, the 3b-th insulating film 105b is formed on the 3a-th insulating film 105a by a step identical to the above-described step illustrated in FIG. 5M (see FIG. 17A). Thereafter, above the upper electrode 14b, and inside the opening H1 of the 3a-th insulating film 105a, the opening H3 of the 3b-th insulating film 105b is formed by a step identical to the above-described step illustrated in FIG. 5N (see FIG. 17B). Subsequently, steps identical to the above-described steps illustrated in FIGS. 5O to 5U are carried out, whereby the active matrix substrate 1F is produced.

### (7-2) Modification Example of Embodiment 3

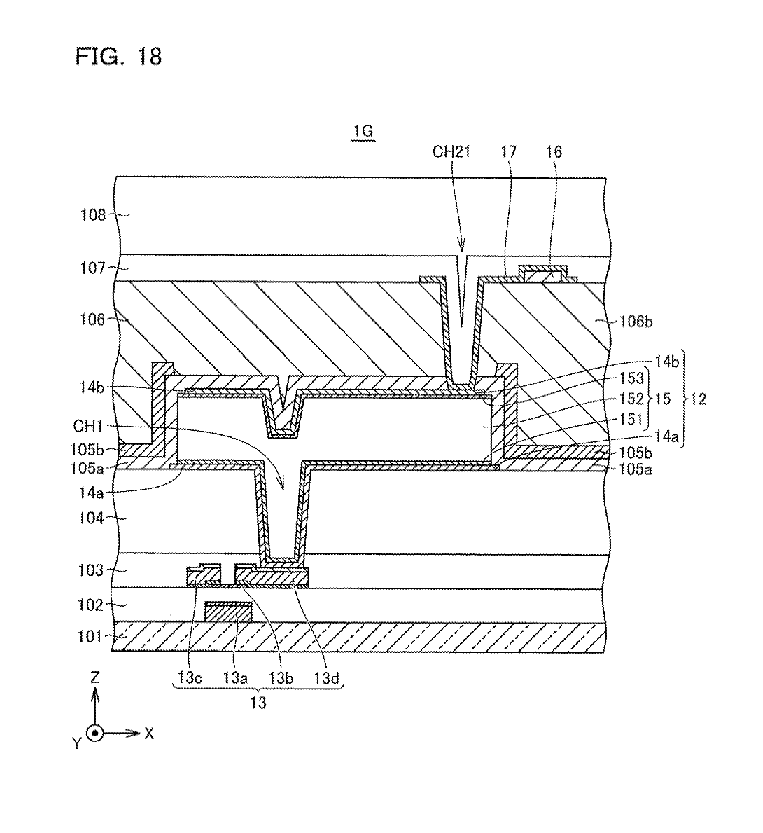

FIG. 18 is a cross-sectional view of a pixel part of an active matrix substrate, which is a cross-sectional view illustrating a structure of Embodiment 3 having a structure in which the 4a-th insulating film 106a is not provided. In FIG. 18, members identical to those in Embodiment 3 are denoted by the same reference symbols as those in Embodiment 3.

As illustrated in FIG. 18, in an active matrix substrate 1G, the 3b-th insulating film 105b is arranged so as to overlap with the 3a-th insulating film 105a covering side surfaces of the photodiode 12. In other words, outside the photodiode 12, the 3b-th insulating film 105b overlaps with the 3a-th insulating film 105a.

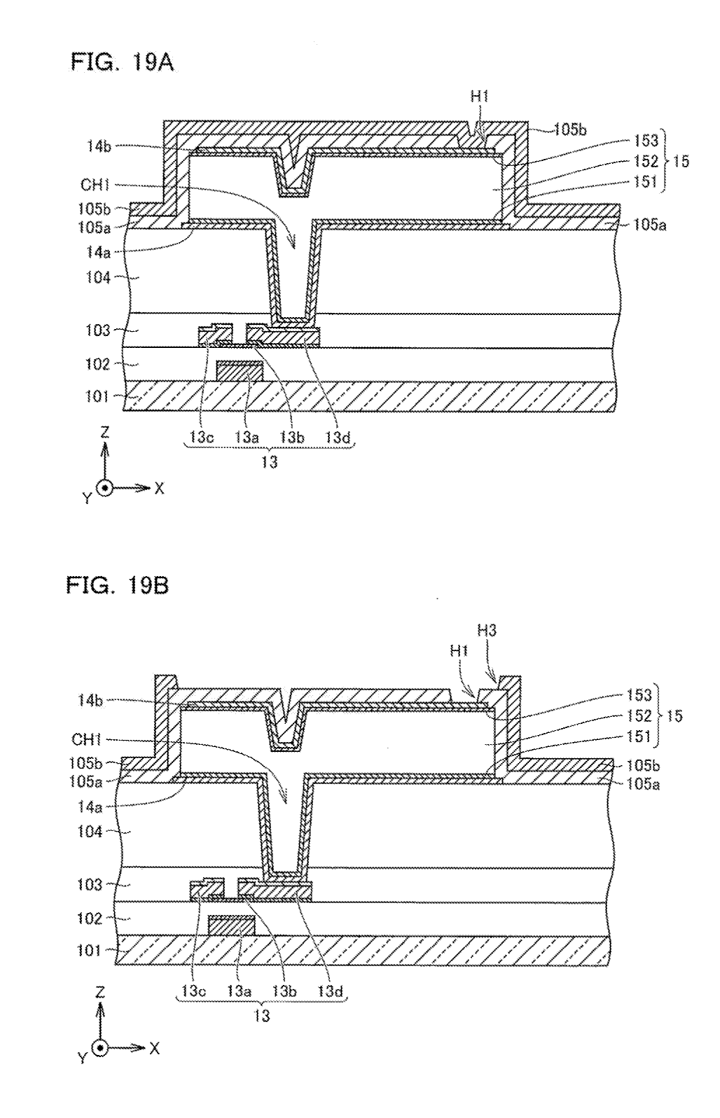

The production of the active matrix substrate 1G is performed as follows. First, a step identical to the above-described step illustrated in FIG. 9A is carried out, and thereafter, the 3b-th insulating film 105b is formed on the 3a-th insulating film 105a by a step identical to the above-described step illustrated in FIG. 9D (see FIG. 19A). Thereafter, the opening H3 of the 3b-th insulating film 105b, which is greater than the opening H1, is formed on the 3a-th insulating film 105a by a step identical to the above-described step illustrated in FIG. 5N (see FIG. 19B). Subsequently, steps identical to the above-described steps illustrated in FIGS. 5O to 5U are carried out, whereby the active matrix substrate 1G is produced.

If moisture penetrates through a scar or the like of the surface of the above-described active matrix substrate 1F, 1G and permeates the 4b-th insulating film 106b, the surface of the 3b-th insulating film 105b is exposed to moisture. Since the 3a-th insulating film 105a is covered with the 3b-th insulating film 105b, however, it is unlikely that moisture would permeate the 3a-th insulating film 105a, even with a discontinuous part being present in the 3a-th insulating film 105a covering the side surfaces of the photodiode 12. This therefore makes it unlikely that leakage current would flow. Besides, since the step of forming the 4a-th insulating film 106a (see FIGS. 5K, 5L) is unnecessary in the case of the above-described configuration, the number of steps for producing the active matrix substrate can be reduced, as compared with Embodiments 1 and 3.

### 7-3

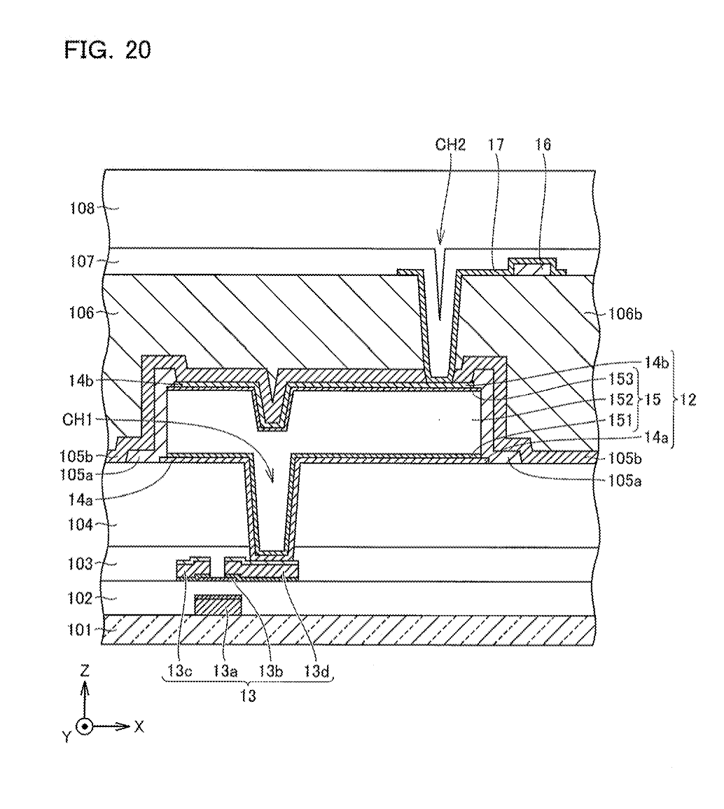

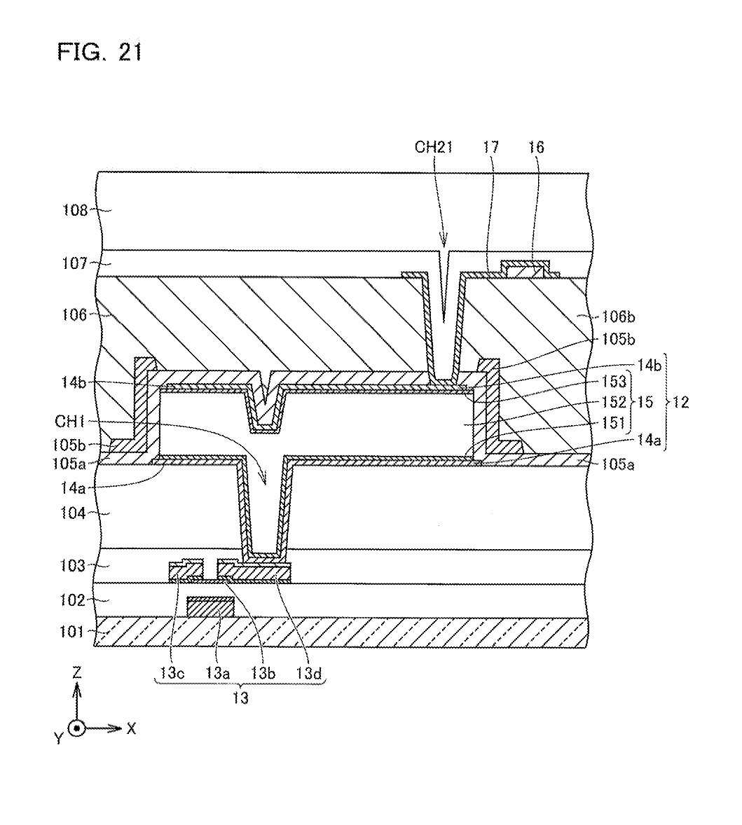

In (7-1) and (7-2) described above, the 3a-th insulating film 105a provided outside the photodiode 12 is extended to the photodiode 12 of the adjacent pixel, but the configuration may be such that, as illustrated in FIG. 20 or FIG. 21, the 3a-th insulating film 105a is not extended to the adjacent pixel, and is positioned apart from the 3a-th insulating film 105a corresponding to the adjacent pixel.

Incidentally, FIG. 20 is a cross-sectional view illustrating the above-described case of FIG. 16 modified so that the 3a-th insulating film 105a is not extended to the adjacent pixel. Further, FIG. 21 is a cross-sectional view illustrating the above-described case of FIG. 18 modified so that the 3a-th insulating film 105a is not extended to the adjacent pixel.

When the active matrix substrate illustrated in FIG. 20 or FIG. 21 is produced, not only the top surface of the upper electrode 14b, but also the 3a-th insulating film 105a on the second insulating film 104 may be etched so as to have a predetermined length in the step illustrated in FIG. 5J.

In the case of the structures illustrated in FIG. 20 and FIG. 21 as well, as is the case with the structures of (7-1) and (7-2) described above, since the 3a-th insulating film 105a is covered with the 3b-th insulating film 105b, it is unlikely that moisture would permeate the 3a-th insulating film 105a, even with a discontinuous part being present in the 3a-th insulating film 105a covering the side surfaces of the photodiode 12. This therefore makes it unlikely that a leakage path would be formed. Besides, since the step of forming the 4a-th insulating film 106a (see FIGS. 5K, 5L) is unnecessary, the number of steps for producing the active matrix substrate can be reduced.

### Embodiment 8

In Embodiments 1 to 7, the 3a-th insulating film 105a and the 3b-th insulating film 105b preferably have a thickness of an integer multiple of 150 nm.

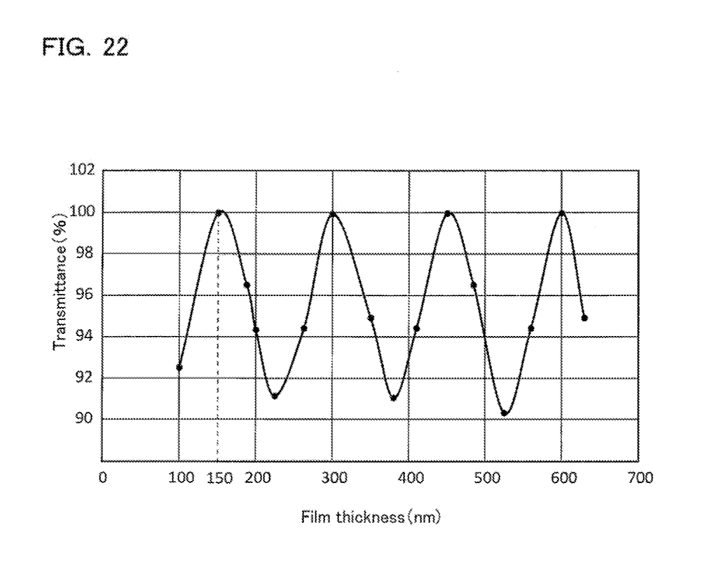

FIG. 22 illustrates a graph of the transmittance of an inorganic insulating film containing SiN when the thickness of the contain inorganic insulating film is varied and is irradiated with light having a wavelength of 550 nm. As illustrated in FIG. 22, in the cases where the thickness is 150 nm, 300 nm, 450 nm, and 600 nm, the transmittance is approximately 100%, but when the thickness is other than these, the transmittance varies in a range of greater than 90% and smaller than 100%.

Accordingly, when the thickness of the inorganic insulating film provided on the photodiode 12 (see FIG. 3 and the like) is set to an integer multiple of 150 nm, the photoelectric conversion efficiency in the photodiode 12 can be enhanced, whereby the X-ray detection accuracy can be improved.

Embodiments of the present invention are thus described above, but the above-described embodiments are merely examples for implementing the present invention. The present invention is not limited to the above-described embodiments, and can be appropriately modified and implemented without departing from the scope of the invention.

### Modification Example 1

In Embodiments 5 and 6 described above, the 4a-th insulating film 106a may be provided not only on the side surface parts of the photodiode 12, but also on the 3a-th insulating film 105a covering the upper electrode 14b. The following description describes such a configuration.

### (1) Modification Example of Embodiment 5

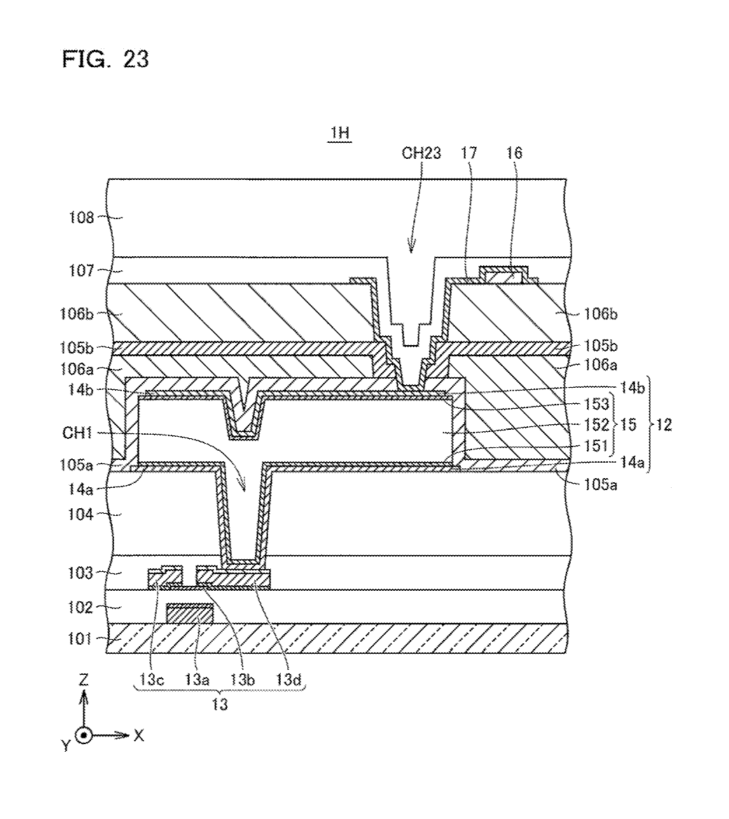

FIG. 23 is a cross-sectional view of a pixel part according to Modification Example of Embodiment 5. In FIG. 23, members identical to those in Embodiment 5 are denoted by the same reference symbols as those in Embodiment 5. The following description principally describes configurations different from those in Embodiment 5.

As illustrated in FIG. 23, in an active matrix substrate 1H according to the present modification example, the 4a-th insulating film 106a is provided not only on side surface parts of the photodiode 12, but also on the 3a-th insulating film 105a covering the upper electrode 14b.

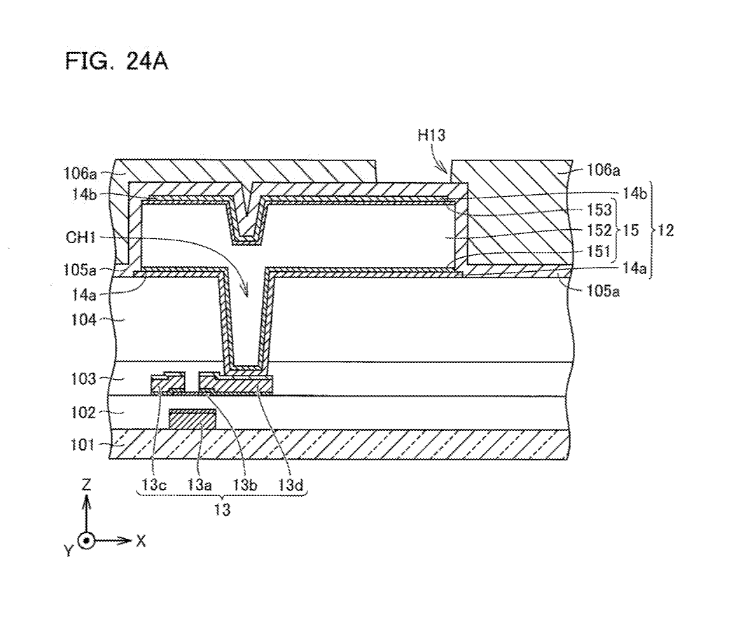

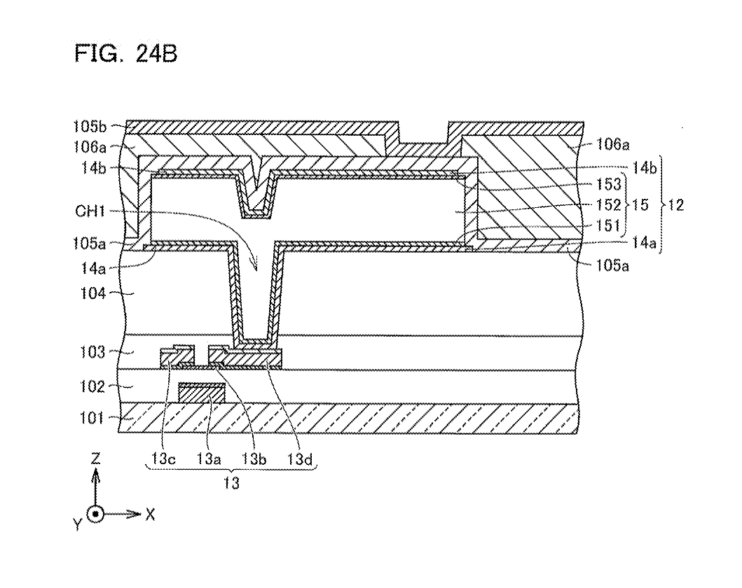

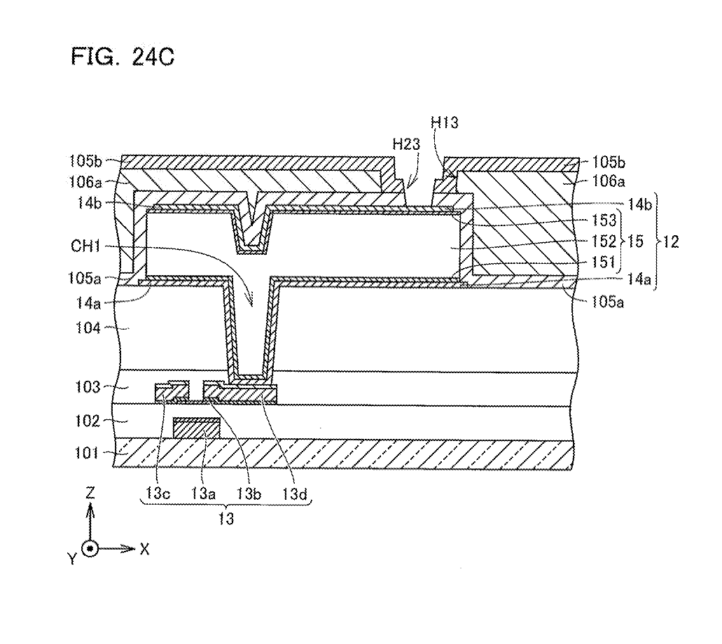

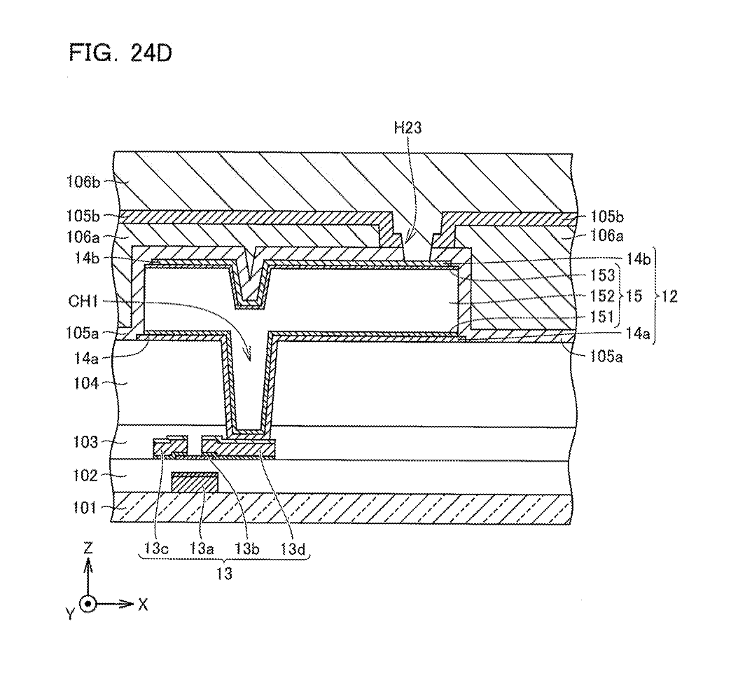

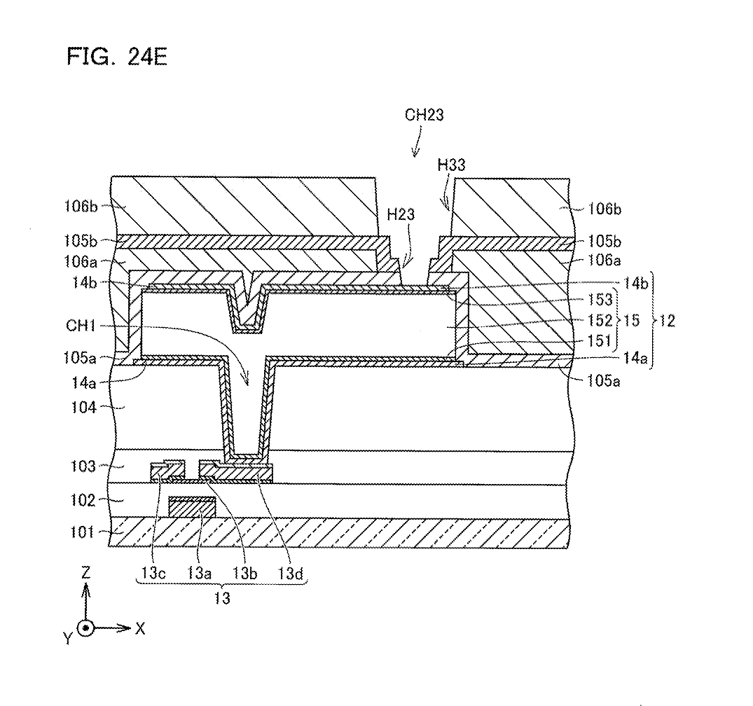

The active matrix substrate 1H of the present modification example can be formed as follows. First, the above-described steps illustrated in FIGS. 5A to 5I and FIG. 13A are carried out, and thereafter, the 4a-th insulating film 106a is patterned by using photolithography (see FIG. 24A). Through these steps, an opening H13 of the 4a-th insulating film 106a is formed on a part of the 3a-th insulating film 105a covering the upper electrode 14b.

Next, the 3b-th insulating film 105b is formed so as to cover the 4a-th insulating film 106a by a step identical to the above-described step illustrated in FIG. 5M (see FIG. 24B). Subsequently, photolithography and dry etching are carried out so that the 3a-th insulating film 105a and the 3b-th insulating film 105b are patterned (see FIG. 240). Through these steps, on the upper electrode 14b, and on an inner side with respect to the opening H13 of the 4a-th insulating film 106a, an opening H23 that passes through the 3a-th insulating film 105a and the 3b-th insulating film 105b is formed.

Incidentally, in the step illustrated in FIG. 240, the same photomask may be used for patterning the 3a-th insulating film 105a and for patterning the 3b-th insulating film 105b, and these insulating films may be simultaneously etched. In the case of doing so, there is no need to prepare respective photomasks for the 3a-th insulating film 105a and the 3b-th insulating film 105b, and the number of the steps can be reduced.

Subsequently, the 4b-th insulating film 106b is form so as to cover the 3b-th insulating film 105b, by the same method as the above-described method illustrated in FIG. 5O (see FIG. 24D), and thereafter, on the opening H23, an opening H33 of the 4b-th insulating film 106b, which is greater than the opening H23, is formed by the same method as the above-described method illustrated in FIG. 5P, whereby a contact hole CH23 composed of the opening H23 and the opening H33 is formed (see FIG. 24E). In the patterning of the 4b-th insulating film 106b, the photomask used for patterning the 4a-th insulating film 106a may be applied. By doing so, the number of photomasks used in patterning the 4b-th insulating film 106b can be reduced.

Thereafter, steps identical to the above-described steps illustrated in FIGS. 5Q to 5U are carried out, whereby the active matrix substrate 1H illustrated in FIG. 23 is produced.

### (2) Modification Example of Embodiment 6

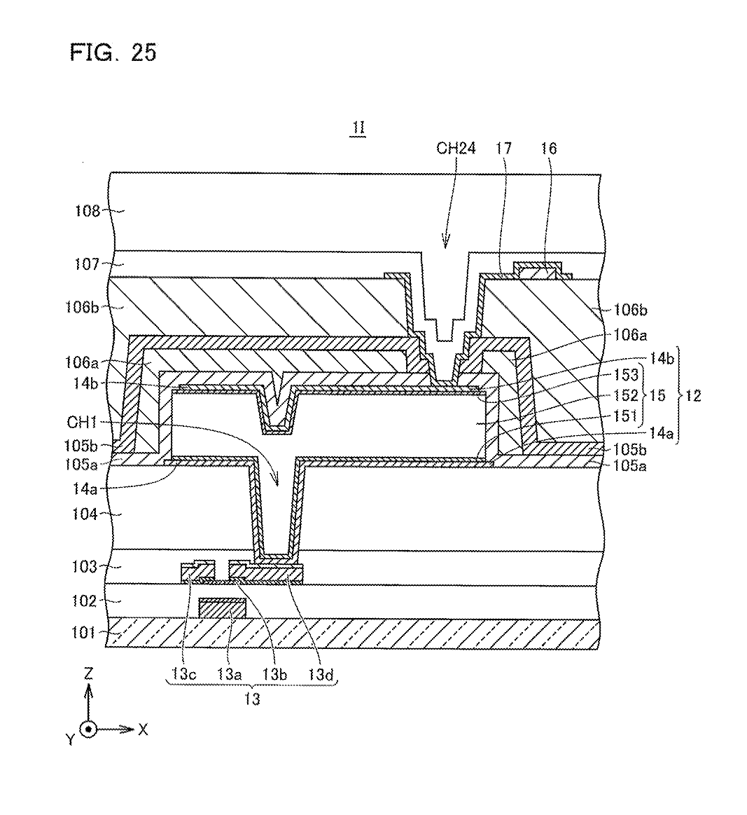

FIG. 25 is a cross-sectional view of a pixel part according to Modification Example of Embodiment 6. In FIG. 25, members identical to those in Embodiment 6 are denoted by the same reference symbols as those in Embodiment 6. The following description principally describes configurations different from those in Embodiment 6.

As illustrated in FIG. 25, in an active matrix substrate 1I according to the present modification example, the 4a-th insulating film 106a is provided not only on side surface parts of the photodiode 12, but also on the 3a-th insulating film 105a covering the upper electrode 14b.

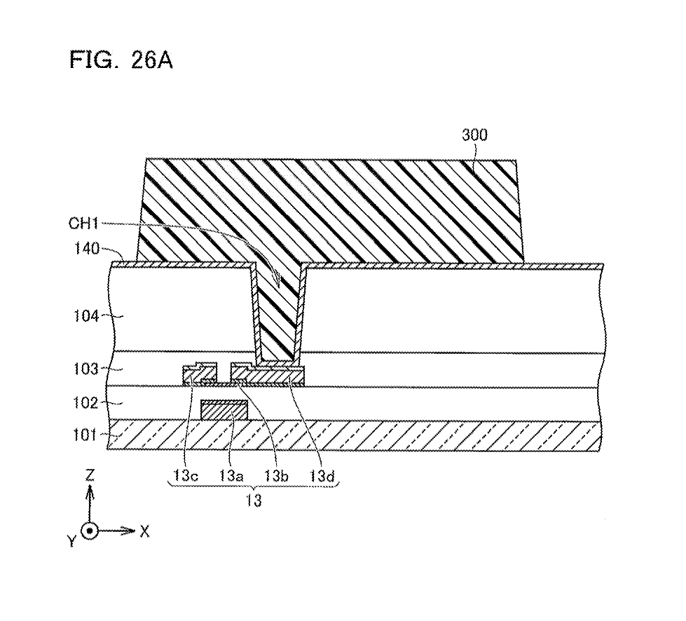

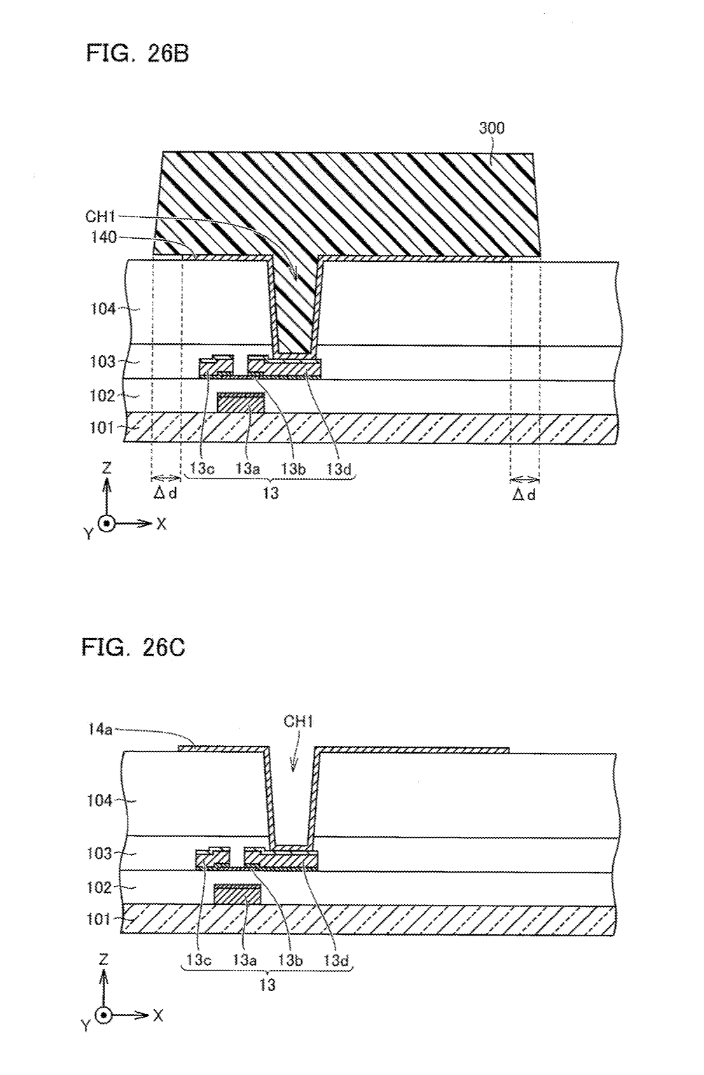

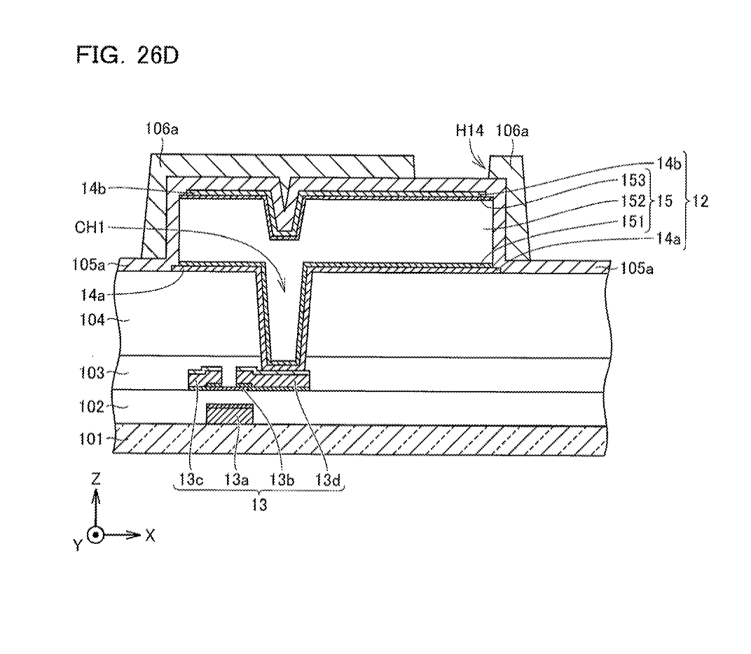

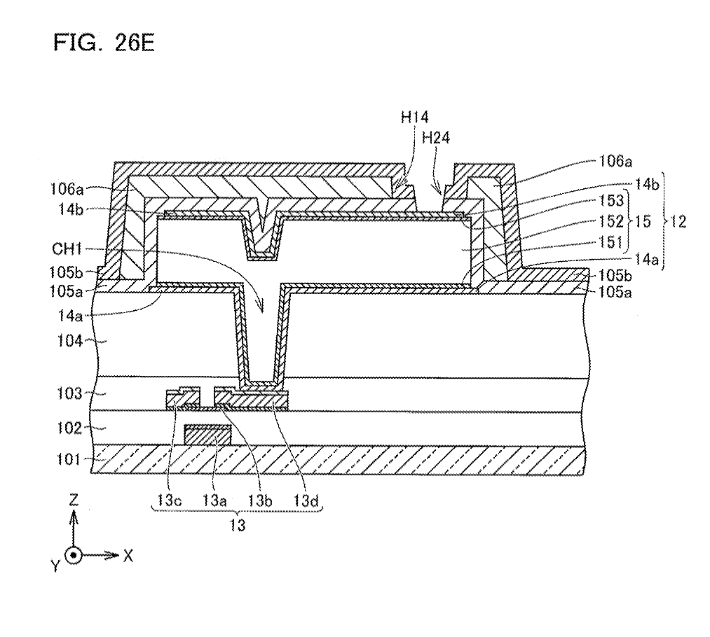

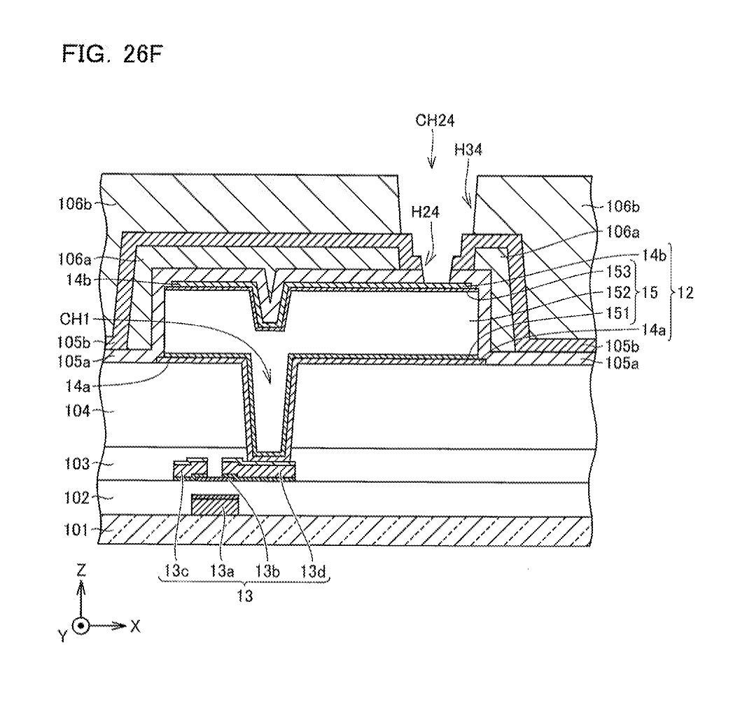

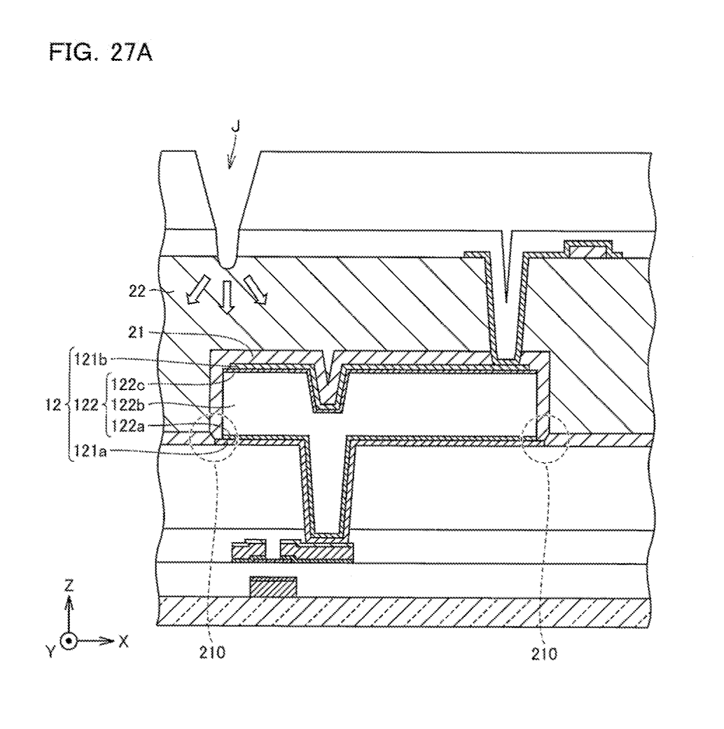

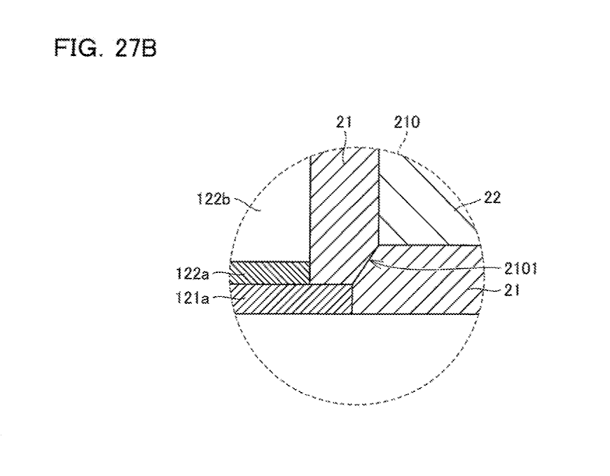

The active matrix substrate 1I of the present modification example can be formed as follows. First, the above-described steps illustrated in FIGS. 5A to 5E are carried out. Subsequently, a metal film 140 made of molybdenum nitride (MoN) is formed by sputtering on the second insulating film 104, and a resist 300 for forming a lower electrode of the photodiode 12 is formed by using photolithography on the metal film 140 (see FIG. 26A).

Then, the metal film 140 is wet-etched (see FIG. 26B). Here, the metal film 140 is etched so that an end of the metal film 140 is arranged on an inner side with respect to the resist 300 by Δd (for example, 2 μm). Thereafter, the resist is removed, whereby the lower electrode 14a is formed (see FIG. 26C).

Incidentally, the photomask used in forming the resist 300 in the step illustrated in FIG. 26A can be also used in a step described below of forming the 4a-th insulating film 106a. By performing the etching in the step illustrated in FIG. 26B in such a manner that an end of the metal film 140 is located on an inner side with respect to the resist 300, the lower electrode 14b is completely covered with the 4a-th insulating film 106a.

Subsequently, after steps identical to those illustrated in FIGS. 5G to 5I, and FIG. 13A are carried out, the 4a-th insulating film 106a on the 3a-th insulating film 105a is patterned by using photolithography (see FIG. 26D). Through this step, an opening H14 of the 4a-th insulating film 106a is formed on a part of the 3a-th insulating film 105a covering the upper electrode 14b.

Subsequently, after the 3b-th insulating film 105b is formed on the 4a-th insulating film 106a by carrying out a step identical to the above-described step illustrated in FIG. 5M, photolithography and dry etching are carried out so that the 3a-th insulating film 105a and the 3b-th insulating film 105b are patterned (see FIG. 26E). Through this step, an opening H24 passing through the 3a-th insulating film 105a and the 3b-th insulating film 105b is formed on the upper electrode 14b, on an inner side with respect to the opening H14 of the 4a-th insulating film 106a.

The respective photomasks when used in forming the lower electrode 14a and forming the 3b-th insulating film 105b can be used as a photomask used for patterning the 4a-th insulating film 106a in the step illustrated in FIG. 26D. With this configuration, there is no need to prepare a photomask exclusively for the 4a-th insulating film 106a, and the number of steps can be reduced. Further, in the step illustrated in FIG. 26E, the same photomask is used for patterning the 3a-th insulating film 105a and the 3b-th insulating film 105b and these insulating films are simultaneously etched. By doing so, there is no need to prepare respective photomasks for the 3a-th insulating film 105a and the 3b-th insulating film 105b, and the number of steps can be reduced.

Subsequently, by a method identical to the above-described method illustrated in FIG. 5O, the 4b-th insulating film 106b is formed so as to cover the 3b-th insulating film 105b, and thereafter, by using a method identical to the above-described method illustrated in FIG. 5P, an opening H34 of the 4b-th insulating film 106b, which is greater than the opening H24, is formed on the opening H24 so that a contact hole CH24 composed of the opening H24 and the opening H34 is formed (see FIG. 26F). For patterning the 4b-th insulating film 106b, the photomask used for patterning the 4a-th insulating film 106a may be used. By doing so, the photomask for patterning the 4b-th insulating film 106b can be omitted.

Thereafter, by carried out steps identical to the above-described steps illustrated in FIGS. 5Q to 5U, the active matrix substrate 1I illustrated in FIG. 25 is produced.

In Modification Examples of Embodiments 5 and 6, the top part of the upper electrode 14b is covered with the 3a-th insulating film 105a and the 4a-th insulating film 106a. Even if moisture penetrates through the 4b-th insulating film 106b, the two insulating films, i.e., the 4a-th insulating film 106a and the 3a-th insulating film 105a, makes it unlikely that moisture would get in, not only the side surface parts of the photodiode 12, but also the top part of the photodiode 12, and a leakage path would be formed.

### DESCRIPTION OF REFERENCE NUMERALS

1. 1A to 1I: active matrix substrate
2: control unit
2A: gate control unit
2B: signal reading unit
3: X-ray source
4: scintillator
10: source line
11: gate line
12: photodiode
13: thin film transistor (TFT)
13a: gate electrode
13b: semiconductor activity layer
13c: source electrode
13d: drain electrode
14a: lower electrode
14b: upper electrode
15: photoelectric conversion layer
16: bias line
100: X-ray imaging device
101: substrate
102: gate insulating film
103: first insulating film
104: second insulating film
105a: 3a-th insulating film
105b: 3b-th insulating film
106a: 4a-th insulating film
106b: 4b-th insulating film
107: fifth insulating film
108: sixth insulating film
151: n-type amorphous semiconductor layer
152: intrinsic amorphous semiconductor layer
153: p-type amorphous semiconductor layer

1. An active matrix substrate having a plurality of pixels,
wherein each of the pixels includes:
a switching element;
a photoelectric conversion element including a pair of electrodes connected with the switching element, and a semiconductor layer provided between the pair of electrodes;
an inorganic film covering a surface of the photoelectric conversion element; and
an organic resin film covering the inorganic film,
wherein the inorganic film includes a first inorganic film, and a second inorganic film provided in a layer different from that of the first inorganic film,
the first inorganic film is provided in contact with at least a side surface of the photoelectric conversion element, and
the second inorganic film is provided so as to be in contact with at least a part of the first inorganic film and cover the side surface of the photoelectric conversion element.

2. The active matrix substrate according to claim 1,
wherein either the first inorganic film or the second inorganic film is arranged so as to be in contact with one of the pair of electrodes.

3. The active matrix substrate according to claim 1,
wherein the first inorganic film is arranged so as to be in contact with one of the pair of electrodes, and
the second inorganic film is arranged so as to overlap with the one of the electrodes with the first inorganic film being interposed therebetween.

4. The active matrix substrate according to claim 1,
wherein the organic resin film includes a first organic resin film, and a second organic resin film provided in a layer different from that of the first organic resin film,
the first organic resin film is provided between the first inorganic film and the second inorganic film, so as to overlap with the side surface of the photoelectric conversion element when viewed in a plan view, and
the second organic resin film is provided so as to cover the second inorganic film.

5. The active matrix substrate according to claim 4,
wherein the first inorganic film and the first organic resin film of each pixel are positioned apart from the first inorganic film and the first organic resin film of another adjacent pixel, respectively.

6. The active matrix substrate according to claim 1,
wherein the first inorganic film and the second inorganic film overlap with each other at the side surface of the photoelectric conversion element, and
the organic resin film is arranged so as to cover the first inorganic film and the second inorganic film.

7. The active matrix substrate according to claim 1,
wherein each of the first inorganic film and the second inorganic film has a thickness of an integer multiple of 150 nm.

8. An X-ray imaging panel comprising:
the active matrix substrate according to claim 1; and
a scintillator that converts irradiated X-rays into scintillation light.
